(19) United States
(12) Patent Application Publication
(10) Pub. No.: US 2020/0006614 A1
(43) Pub. Date: Jan. 2, 2020

(54) THERMOELECTRIC CONVERSION DEVICE

(71) Applicant: TDK CORPORATION, Tokyo (JP)

(72) Inventors: Makoto SHIBATA, Tokyo (JP); Kazuya MAEKAWA, Tokyo (JP); Takashi ASATANI, Tokyo (JP)

(73) Assignee: TDK CORPORATION, Tokyo (JP)

(21) Appl. No.: 16/490,405

(22) PCT Filed: Jul. 31, 2017
(86) PCT No.: PCT/JP2017/027676

§ 371 Date: Aug. 30, 2019

(30) Foreign Application Priority Data
Mar. 3, 2017 (JP) 2017-040521

(51) Int. Cl. H01L 35/30; H01L 35/32; H01L 35/34

(52) U.S. Cl. CPC H01L 35/30; H01L 35/04; H01L 35/34; H01L 35/32

(57) ABSTRACT

A thermoelectric conversion device includes: a substrate that includes a first surface and a second surface facing each other in a thickness direction; thermoelectric conversion elements that are disposed on a side of the first surface of the substrate; and a plurality of heat transfer parts that are formed with spaces interposed therebetween in a first direction along an in-plane direction of the substrate, and that are configured to transfer heat from/to the thermoelectric conversion elements, wherein a low heat conduction part having a lower thermal conductivity than a thermal conductivity of the heat transfer parts is disposed between the heat transfer parts adjacent to each other in the first direction.

### TECHNICAL FIELD

The present disclosure relates to a thermoelectric conversion device.

Priority is claimed on Japanese Patent Application No. 2017-040521, filed Mar. 3, 2017, the content of which is incorporated herein by reference.

### BACKGROUND ART

In recent years, from the point of view of energy saving, the use of heat that dissipates without being used has attracted attention. Particularly, in the field relating to internal combustion engines and combustion apparatuses, research relating to thermoelectric conversion using exhaust heat has been actively performed.

In research on thermoelectric conversion devices, although BiTe-based materials having a high performance near room temperature have been mainstream until now, the improvement in thermoelectric efficiency of such types of material has come close to its limit in addition to problems of toxicity and an increase in material costs thereof, and thus, such materials have tended to deviate from mainstream research. Thus, in recent years, the focus of research has shifted in a direction of lowering the thermal conductivity using a quantum structure using a multiplayer film, a nano composite mixture film, or the like instead of BiTe-based materials and improving thermoelectric efficiency in accordance therewith.

For example, as illustrated in Patent Document 1, a thermoelectric conversion module (thermoelectric conversion device) including a substrate formed with a uniform thickness over its entire surface, a thermoelectric conversion film formed on a first surface of the substrate, a first heat transfer member disposed on the first surface side of the substrate, and a second heat transfer member disposed on a second surface side of the substrate that is positioned on a side opposite to the first surface is known.

A convex part is disposed in one surface of the first heat transfer member and the second heat transfer member. The convex part of the first heat transfer member is in contact with an electrode on a high-temperature side formed in one end portion of the thermoelectric conversion film. The convex part of the second heat transfer member is in contact with a part, which faces an electrode on a low-temperature side formed in the other end portion of the thermoelectric conversion film in the thickness direction of the substrate, of the second surface of the substrate.

### CITATION LIST

### Patent Document

### Patent Document 1

PCT International Publication No. WO 2011/065185

### SUMMARY OF INVENTION

### Technical Problem

In the conventional thermoelectric conversion module described above, when heat from the first heat transfer member is transferred to the thermoelectric conversion film through the convex part, heat is transferred also to the substrate through the thermoelectric conversion film. At this time, since the thickness of the substrates is uniform over the entire surface, heat transferred to the substrate may easily move to uniformly spread in an in-plane direction of the substrate. For this reason, transfer of heat from a hot junction side to a cold junction side of the thermoelectric conversion film is promoted through the substrate, and the temperature of the cold junction side of the thermoelectric conversion film may easily rise.

Accordingly, a temperature difference between the hot junction side and the cold junction side of the thermoelectric conversion film becomes small, and there is a problem in that the amount of generated power is small.

The present disclosure has been realized in consideration of such situations, and an objective thereof is to provide a thermoelectric conversion device capable of acquiring a large amount of generated electric power.

### Solution to Problem

(1) According to the present disclosure, a thermoelectric conversion device is provided, including: a substrate that includes a first surface and a second surface facing each other in a thickness direction, thermoelectric conversion elements that are disposed on a side of the first surface of the substrate; and a plurality of heat transfer parts that are formed with spaces interposed therebetween in a first direction along an in-plane direction of the substrate, and that are configured to transfer heat from/to the thermoelectric conversion elements, wherein a low heat conduction part having a lower thermal conductivity than a thermal conductivity of the heat transfer parts is disposed between heat transfer parts adjacent to each other in the first direction, and a thickness of at least a part of facing portions of the substrate that face the thermoelectric conversion elements in the thickness direction is smaller than a thickness of at least a part of other part of the substrate.

According to the thermoelectric conversion device relating to the present disclosure, since a low heat conduction part having lower thermal conductivity than a thermal conductivity of the heat transfer parts is disposed between the heat transfer parts adjacent to each other in the first direction, heat transfer from/to the thermoelectric conversion elements through the heat transfer parts can be performed with priority over heat transfer through the low heat conduction part. Accordingly, for example, in a case in which heat is transferred to the thermoelectric conversion elements through the heat transfer parts, an end portion of the thermoelectric conversion elements that are close to the heat transfer parts can be set as an end portion of a hot junction side, and an end portion away from the end portion of the hot junction side when seen from the heat transfer parts in an in-plane direction of the substrate can be set as an end portion of a cold junction side. Accordingly, a temperature difference can be configured to occur between the hot junction side and the cold junction side in the thermoelectric conversion elements, and an amount of generated power can be achieved by generating an electromotive force based on the Seebeck effect.

Meanwhile in the case described above, heat transferred from the heat transfer parts to the thermoelectric conversion elements is not only conducted from the hot junction side to the cold junction side inside the thermoelectric conversion elements but also is transferred mainly from the hot junction side of the thermoelectric conversion elements to the substrate and is dissipated or cooled through the substrate. At this time, the substrate is not formed with a uniform thickness over the entire face unlike a conventional case, and a thickness of at least the part of the facing portions facing the thermoelectric conversion elements in the substrate in the thickness direction is formed to be smaller than a thickness of at least another part of the substrate. Accordingly, heat transferred to the substrate can be inhibited from moving from the hot junction side to the cold junction side inside the substrate. In other words, by using a change in the thickness of the substrate, conduction of heat from the hot junction side to the cold junction side inside the substrate can be inhibited.

In this way, a decrease in the temperature difference occurring between the hot junction side and the cold junction side in the thermoelectric conversion elements due to the influence of conduction of heat through the substrate can be inhibited, and a large amount of generated power can be achieved.

In addition, for example, also in a case in which heat is transferred from the substrate side to the thermoelectric conversion elements, similar to the case described above, by using a change in the thickness of the substrate, conduction of heat from the hot junction side to the cold junction side inside the substrate can be inhibited. Accordingly, a decrease in the temperature difference occurring between the hot junction side and the cold junction side in the thermoelectric conversion elements due to the influence of conduction of heat through the substrate can be inhibited, and a large amount of generated power can be achieved.

(2) In the thermoelectric conversion device, a first heat transfer member disposed on the side of the first surface of the substrate may be included, and the thermoelectric conversion elements and the heat transfer parts may be disposed on a substrate side of the first heat transfer member.

In such a case, for example, the first heat transfer member can be caused to function as a heat-receiving member, and heat received by the first heat transfer member can be transferred to the thermoelectric conversion elements through the heat transfer parts with priority. Accordingly, a temperature difference between the hot junction side and the cold junction side in the thermoelectric conversion elements can be effectively increased. In addition, for example, in a case in which heat is transferred from the substrate side to the thermoelectric conversion elements, a heat dissipation or a cooling effect using the first heat transfer member can be used, and accordingly, similarly, a temperature difference between the hot junction side and the cold junction side in the thermoelectric conversion elements can be effectively increased.

Accordingly, by including the first heat transfer member, a temperature difference between the hot junction side and the cold junction side in the thermoelectric conversion elements can be effectively increased, and a large amount of generated power can be achieved.

(3) The low heat conduction part may be an air gap portion.

In such a case, the low heat conduction part is an air gap portion, a so-called a gap filled with the air, and accordingly, the low heat conduction part can be simply configured. In addition, since the thermal conductivity of the low heat conduction part can be configured to be much lower than that of the heat transfer parts, heat can be transferred more selectively between the heat transfer parts and the thermoelectric conversion elements, and a large amount of generated power is easily achieved.

(4) A thickness of first parts of the substrate may be larger than the thickness of at least the part of the facing portions, and each of the first parts of the substrate is positioned in a middle of the heat transfer parts, which are adjacent to each other in the first direction, in the first direction.

In such a case, since a thickness of the first parts is larger than a thickness of at least the part of the facing portions (in other words, a thickness of a part of the facing portions that are smaller than a thickness of at least another part of the substrate), for example, in a case in which heat is transferred to the thermoelectric conversion elements through the heat transfer parts, an end portion of the thermoelectric conversion elements on the cold junction side can be cooled with high efficiency in accordance with a heat dissipation or a cooling effect of the first parts of the substrate. Accordingly, a temperature difference between the hot junction side and the cold junction side in the thermoelectric conversion elements can be further increased, and a large amount of generated power can be achieved. Therefore, this is particularly effective in a case in which heat is transferred to the thermoelectric conversion elements through the heat transfer parts.

(5) A thickness of at least a part of second parts of the substrate that faces the heat transfer parts in the thickness direction may be larger than the thickness of at least the part of the facing portions.

In such a case, since a thickness of at least the part of the second parts is larger than a thickness of at least the part of the facing portions (in other words, a thickness of a part of the facing portions that are smaller than a thickness of at least another part of the substrate), for example, in a case in which heat is transferred to the thermoelectric conversion elements through the heat transfer parts, heat transferred from the hot junction side of the thermoelectric conversion elements to the substrate can be dissipated or cooled through the second parts of the substrate rather than being moved in the in-plane direction of the substrate. In this way, conduction of heat from the hot junction side to the cold junction side inside the substrate can be further inhibited. Accordingly, a temperature difference between the hot junction side and the cold junction side in the thermoelectric conversion elements can be further increased, and a larger amount of generated power can be achieved.

Particularly, this case is effective in a case in which the amount of heat received by the heat transfer part side is larger, and a temperature difference between the hot junction side and the cold junction side in the thermoelectric conversion elements can be secured while releasing a part of the heat, and a large amount of generated power can be achieved.

In addition, for example, in a case in which heat is transferred from the side of the substrate to the thermoelectric conversion elements, the heat transferred to the substrate can be dissipated or cooled through the second parts of the substrate and the heat transfer parts rather than being moved in the in-plane direction of the substrate. Accordingly, conduction of heat from the hot junction side to the cold junction side inside the substrate can be inhibited, and, similar to the case described above, a temperature difference occurring between the hot junction side and the cold junction side in the thermoelectric conversion elements can be increased.

(6) A thickness of first parts of the substrate may be larger than the thickness of at least the part of the facing portions, each of the first parts of the substrate is positioned in a middle of the heat transfer parts, which are adjacent to each other in the first direction, in the first direction, and a thickness of at least a part of a second parts of the substrate that faces the heat transfer parts in the thickness direction may be larger than the thickness of at least the part of the facing portions.

In such a case, a thickness of the first parts and a thickness of at least the part of the second parts are larger than a thickness of at least the part of the facing portions (in other words, a thickness of a part of the facing portions that are smaller than a thickness of at least another part of the substrate). Accordingly, for example, in a case in which heat is transferred to the thermoelectric conversion elements through the heat transfer parts, heat transferred from the hot junction side of the thermoelectric conversion elements to the substrate can be dissipated or cooled through the second parts of the substrate rather than being moved in the in-plane direction of the substrate. In addition, simultaneously with this, an end portion of the thermoelectric conversion elements on the cold junction side can be cooled with high efficiency in accordance with a heat dissipation or a cooling effect of the first parts of the substrate.

Accordingly, since both the heat dissipation or cooling effect using the second parts of the substrate and the heat dissipation or cooling effect using the first parts of the substrate can be used, a temperature difference between the hot junction side and the cold junction side in the thermoelectric conversion elements can be stably increased without being likely to be influenced by the amount of heat transferred to the thermoelectric conversion elements through the heat transfer parts. Accordingly, a large amount of generated power can be achieved more stably. Therefore, this is particularly effective in a case in which heat is transferred to the thermoelectric conversion elements through the heat transfer parts.

(7) A width of the part of the second parts, which have a larger thickness than the thickness of at least the part of the facing portions, in the first direction may be larger than a width of a part of the first parts, which is larger than the thickness of at least the part of the facing portions, in the first direction.

In such a case, for example, in a case in which heat is transferred to the thermoelectric conversion elements through the heat transfer parts, the heat dissipation or cooling effect using the second parts of the substrate can be successfully achieved more effectively than the heat dissipation or cooling effect using the first parts of the substrate. Accordingly, for example, in a case in which the amount of heat transferred to the thermoelectric conversion elements through the heat transfer parts is large, a part of the heat can be easily released to the outside through the second parts of the substrate. Accordingly, heat transfer of a large amount of heat from the hot junction side to the cold junction side inside the substrate can be effectively inhibited. Accordingly, also in a case in which the amount of heat transferred to the thermoelectric conversion elements through the heat transfer parts is large, a temperature difference between the hot junction side and the cold junction side in the thermoelectric conversion elements can be increased, and a large amount of generated power can be achieved.

(8) A width of a part of the first parts, which have a larger thickness than the thickness of at least the part of the facing portions, in the first direction may be larger than a width of the part of the second parts, which is larger than the thickness of at least the part of the facing portions, in the first direction.

In such a case, for example, in a case in which heat is transferred to the thermoelectric conversion elements through the heat transfer parts, the heat dissipation or cooling effect using the first parts of the substrate can be successfully achieved more effectively than the heat dissipation or cooling effect using the second parts of the substrate. Accordingly, the cold junction side of the thermoelectric conversion elements can be easily cooled effectively using the heat dissipation or cooling effect in the first parts of the substrate. Accordingly, a temperature difference between the hot junction side and the cold junction side in the thermoelectric conversion elements can be increased, and a large amount of generated power can be achieved.

(9) In the thermoelectric conversion device described in (4), a second heat transfer member disposed on a side of the second surface of the substrate is further included, and the second heat transfer member may be thermally bonded to the first parts of the substrate and is configured to transfer heat from/to the first parts rather than the facing portions.

In such a case, for example, in a case in which heat is transferred to the thermoelectric conversion elements through the heat transfer parts, the cold junction side of the thermoelectric conversion elements through the first parts of the substrate can be easily cooled more effectively using the heat dissipation or cooling effect using the second heat transfer member. Accordingly, a temperature difference between the hot junction side and the cold junction side in the thermoelectric conversion elements can be increased, and a large amount of generated power can be achieved.

(10) In the thermoelectric conversion device described in (5), a thermoelectric conversion module in which substrates with the thermoelectric conversion elements are piled up in the thickness direction in multiple layers may be further included, wherein, when a direction from the second surface to the first surface is defined as an upward direction, the heat transfer parts may be configured to heat from/to the thermoelectric conversion element positioned in an uppermost layer in the thickness direction among the thermoelectric conversion elements piled up in multiple layers, and the thermoelectric conversion elements positioned in a layer other than the uppermost layer in the thickness direction among the thermoelectric conversion elements piled up in multiple layers may be thermally bonded to the second parts of each of the substrates positioned in a layer above thereof and are configured to transfer heat from/to the second parts of each of the substrates positioned in the layer above thereof rather than the facing portions of each of the substrates positioned in the layer above thereof.

In such a case, since the thermoelectric conversion module in which the substrates and the thermoelectric conversion elements are configured in multiple layers is included, for example, in a case in which heat is transferred to the thermoelectric conversion elements positioned in the uppermost layer through the heat transfer parts, heat dissipated through the second parts of the substrate positioned in the uppermost layer can be transferred to an end portion of the thermoelectric conversion elements on the hot junction side that is positioned in a layer below the substrate, and accordingly, a larger amount of generated power can be achieved using this thermoelectric conversion elements. In this way, the substrates and the thermoelectric conversion elements are configured in multiple layers, the dissipated heat can be effectively used, and power generation in the thermoelectric conversion elements of each layer can be achieved. Accordingly, a large amount of generated power can be achieved with high efficiency.

(11) In the thermoelectric conversion device described in (10), a second heat transfer member disposed on a side of the second surface of the substrate positioned in a lowermost layer in the thickness direction among the substrates piled up in multiple layers may be further included, wherein the second heat transfer member may be thermally bonded to the second parts of the substrate positioned in the lowermost layer among the substrates piled up in multiple layers, and the second heat transfer member is configured to transfer heat from/to the second parts of the substrate positioned in the lowermost layer rather than the facing portions of the substrate positioned in the lowermost layer.

In such a case, the second heat transfer member can be used as a heat-receiving member, and also a case in which heat is transferred from the second heat transfer member side can be handled. In other words, heat received by the second heat transfer member can be transferred to the end portion of the thermoelectric conversion elements on the hot junction side that is positioned in the lowermost layer through the second parts of the substrate positioned in the lowermost layer, and heat dissipated through the second parts of the substrate positioned in the lowermost layer can be transferred to the end portion of the thermoelectric conversion elements on the hot junction side that is positioned in the second layer through the second parts of the substrate of the second layer positioned in the layer above of the substrate. In this way, also in a case in which heat is transferred from the second heat transfer member side, dissipated heat can be effectively used, and power generation can be achieved in the thermoelectric conversion elements of each layer. Accordingly, a large amount of generated power can be achieved with high efficiency.

Particularly, a case in which heat is transferred to the thermoelectric conversion elements positioned in the uppermost layer through the heat transfer parts, and heat is transferred to the thermoelectric conversion elements positioned in the lowermost layer through the second heat transfer member, in other words, also a case in which heat is transferred from both sides in the thickness direction can be appropriately handled.

(12) In the thermoelectric conversion device described in (4), a thermoelectric conversion module in which substrates with the thermoelectric conversion elements are piled up in the thickness direction in multiple layers may be further included, wherein, when a direction from the second surface to the first surface is defined as an upward direction, the heat transfer parts may be configured to heat from/to the thermoelectric conversion element positioned in an uppermost layer in the thickness direction among the thermoelectric conversion elements piled up in multiple layers, and the thermoelectric conversion elements positioned in a layer other than the uppermost layer in the thickness direction among the thermoelectric conversion elements piled up in multiple layers may be thermally bonded to the first parts of each of the substrates positioned in a layer above thereof, and are configured to transfer heat from/to the first parts of each of the substrates positioned in the layer above thereof rather than the facing portions of each of the substrates positioned in the layer above thereof.

In such a case, since the thermoelectric conversion module in which the substrates and the thermoelectric conversion elements are configured in multiple layers is included, power generation can be achieved in the thermoelectric conversion elements of each layer. Accordingly, a large amount of generated power can be achieved with high efficiency. Particularly, for example, in a case in which heat is transferred to the thermoelectric conversion elements positioned in the uppermost layer through the heat transfer parts, an end portion of the thermoelectric conversion elements of each layer on the cold junction side can be cooled through the first parts of the substrate of each layer with high efficiency, and accordingly, a temperature difference between the hot junction side and the cold junction side in the thermoelectric conversion elements of each layer can be effectively increased. Accordingly, in this way, a large amount of generated power can be easily achieved.

(13) In the thermoelectric conversion device described in any one of (6) to (8), a thermoelectric conversion module in which substrates with the thermoelectric conversion elements are piled up in the thickness direction in multiple layers may be further included, wherein, when a direction from the second surface to the first surface is defined as an upward direction, the heat transfer parts may be configured to transfer heat from/to the thermoelectric conversion elements positioned in an uppermost layer in the thickness direction among the thermoelectric conversion elements piled up in multiple layers, and the thermoelectric conversion elements positioned in a layer other than the uppermost layer in the thickness direction among the thermoelectric conversion elements piled up in multiple layers may be thermally bonded to the first parts and the second parts of each of the substrates positioned in a layer above thereof, and are configured to transfer heat from/to the first parts and the second parts of each of the substrates positioned in the layer above thereof rather than the facing portions of each of the substrates positioned in the layer above thereof.

In such a case, since the thermoelectric conversion module in which the substrates and the thermoelectric conversion elements are configured in multiple layers is included, for example, in a case in which heat is transferred to the thermoelectric conversion elements positioned in the uppermost layer through the heat transfer parts, heat dissipated through the second parts of the substrate positioned in the uppermost layer can be transferred to an end portion of the thermoelectric conversion elements on the hot junction side that is positioned in a layer below the substrate, and accordingly, a larger amount of generated power can be achieved using these thermoelectric conversion elements. In this way, the substrates and the thermoelectric conversion elements are configured in multiple layers, the dissipated heat can be effectively used, and power generation in the thermoelectric conversion elements of each layer can be achieved. Accordingly, a large amount of generated power can be achieved with high efficiency.

In addition, since the end portion of the thermoelectric conversion elements of each layer on the cold junction side can be cooled with high efficiency through the first parts of each of the substrates in each layer, a temperature difference between the hot junction side and the cold junction side in the thermoelectric conversion elements of each layer can be effectively increased. Therefore, in accordance with this, a large amount of generated power can be easily achieved.

(14) In the thermoelectric conversion device described in (12) or (13), a second heat transfer member disposed on a side of the second surface of the substrate positioned in a lowermost layer in the thickness direction among the substrates piled up in multiple layers is further included, wherein the second heat transfer member may be thermally bonded to the first parts of the substrate positioned in the lowermost layer among the substrates piled up in multiple layers, and the second heat transfer member is configured to transfer heat from/to the first parts of the substrate positioned in the lowermost layer rather than the facing portions of the substrate positioned in the lowermost layer.

In such a case, for example, in a case in which heat is transferred to the thermoelectric conversion elements positioned in the uppermost layer through the heat transfer parts, the end portion of the thermoelectric conversion elements on the cold junction side can be effectively cooled through the first parts of the substrate positioned in the lowermost layer using a cooling effect using the second heat transfer member. For this reason, as a result, the end portion of the thermoelectric conversion elements of each layer on the cold junction side can be effectively cooled through the first parts of each of the substrates of each layer, and a temperature difference between the hot junction side and the cold junction side in the thermoelectric conversion elements of each layer can be effectively increased.

### Advantageous Effects of Invention

According to the present disclosure, a large amount of generated power can be achieved using changes in the thickness of the substrate, and a thermoelectric conversion device having high quality and high performance of which a thermoelectric conversion efficiency is superior can be configured.

### BRIEF DESCRIPTION OF DRAWINGS

FIG. 1 is an exploded perspective view illustrating a thermoelectric conversion device according to a first embodiment of the present disclosure.

FIG. 2 is a plan view of a substrate illustrated in FIG. 1 that is seen from a side of a first principal surface.

FIG. 3 is a longitudinal sectional view of a thermoelectric conversion device taken along line A-A illustrated in FIG. 1.

FIG. 4 is a diagram illustrating a modified example of the first embodiment and is a longitudinal sectional view (a longitudinal sectional view corresponding to a viewpoint illustrated in FIG. 3) of a thermoelectric conversion device.

FIG. 5 is a longitudinal sectional view (a longitudinal sectional view corresponding to a viewpoint illustrated in FIG. 3) of a thermoelectric conversion device according to a second embodiment of the present disclosure.

FIG. 6 is a longitudinal sectional view (a longitudinal sectional view corresponding to a viewpoint illustrated in FIG. 3) of a thermoelectric conversion device according to a third embodiment of the present disclosure.

FIG. 7 is a diagram illustrating a modified example of the third embodiment and is a longitudinal sectional view (a longitudinal sectional view corresponding to a viewpoint illustrated in FIG. 3) of a thermoelectric conversion device.

FIG. 8 is a diagram illustrating another modified example of the third embodiment and is a longitudinal sectional view (a longitudinal sectional view corresponding to a viewpoint illustrated in FIG. 3) of a thermoelectric conversion device.

FIG. 9 is a longitudinal sectional view (a longitudinal sectional view corresponding to a viewpoint illustrated in FIG. 3) of a thermoelectric conversion device according to a fourth embodiment of the present disclosure.

FIG. 10 is a longitudinal sectional view (a longitudinal sectional view corresponding to a viewpoint illustrated in FIG. 3) of a thermoelectric conversion device according to a fifth embodiment of the present disclosure.

FIG. 11 is a longitudinal sectional view (a longitudinal sectional view corresponding to a viewpoint illustrated in FIG. 3) of a thermoelectric conversion device according to a sixth embodiment of the present disclosure.

FIG. 12 is a diagram illustrating a modified example of the sixth embodiment and is a longitudinal sectional view (a longitudinal sectional view corresponding to a viewpoint illustrated in FIG. 3) of a thermoelectric conversion device.

FIG. 13 is a diagram illustrating another modified example of the first embodiment and is a longitudinal sectional view (a longitudinal sectional view corresponding to a viewpoint illustrated in FIG. 3) of a thermoelectric conversion device.

FIG. 14 is a diagram illustrating yet another modified example of the first embodiment and is a longitudinal sectional view (a longitudinal sectional view corresponding to a viewpoint illustrated in FIG. 3) of a thermoelectric conversion device.

FIG. 15 is a diagram illustrating yet another modified example of the first embodiment and is a longitudinal sectional view (a longitudinal sectional view corresponding to a viewpoint illustrated in FIG. 3) of a thermoelectric conversion device.

FIG. 16 is a plan view of a substrate illustrated in FIG. 15 that is seen from a side of a first principal surface.

FIG. 17 is a diagram illustrating yet another modified example of the first embodiment and is a longitudinal sectional view (a longitudinal sectional view corresponding to a viewpoint illustrated in FIG. 3) of a thermoelectric conversion device.

FIG. 18 is a diagram illustrating a modified example of a thermoelectric conversion device according to the present disclosure and is a longitudinal sectional view (a longitudinal sectional view corresponding to a viewpoint illustrated in FIG. 3) of the thermoelectric conversion device.

FIG. 19 is a diagram illustrating a modified example of the fifth embodiment and is a longitudinal sectional view (a longitudinal sectional view corresponding to a viewpoint illustrated in FIG. 3) of a thermoelectric conversion device.

### DESCRIPTION OF EMBODIMENTS

### First Embodiment

Hereinafter, a thermoelectric conversion device according to a first embodiment of the present disclosure will be described with reference to the drawings.

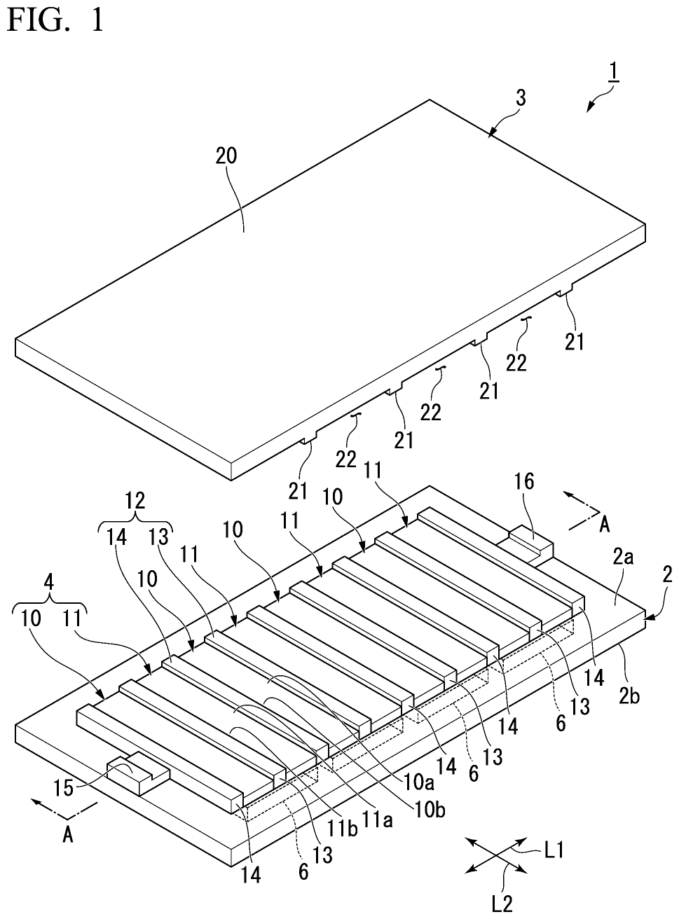

As illustrated in FIGS. 1 to 3, the thermoelectric conversion device 1 according to this embodiment includes: a substrate 2 having a first principal surface (a first surface according to the present disclosure) 2a and a second principal surface (a second surface according to the present disclosure) 2b facing each other in a thickness direction; a first heat transfer plate (a first heat transfer member according to the present disclosure) 3 disposed on a side of the first principal surface 2a of the substrate 2; and a thermoelectric conversion film (a thermoelectric conversion elements according to the present disclosure) 4 disposed between the substrate 2 and the first heat transfer plate 3. In other words, the thermoelectric conversion film 4 is disposed on a further side of the substrate 2 than the first heat transfer plate 3.

In this embodiment, a side of a first heat transfer plate 3 along the thickness direction of the substrate 2 will be referred to as an upper side, and a side opposite thereto will be referred to as a lower side. In other words, a direction from the second principal surface 2b to the first principal surface 2a of the substrate 2 will be referred to as an upward direction, and a direction opposite thereto will be referred to as a downward direction. In addition, one direction out of directions along the in-plane of the substrate 2 will be referred to as a first direction L1, and a direction orthogonal to the first direction L1 will be referred to as a second direction L2.

In this embodiment, a case in which heat is transferred from a side of the first heat transfer plate 3 to a side of the thermoelectric conversion film 4 will be described as an example. However, the embodiment is not limited to such a case, and heat may be transferred from a side the substrate 2 to a side of the thermoelectric conversion film 4.

### (Substrate)

The substrate 2 is formed in a rectangular shape that is longer in a first direction L1 than in a second direction L2 in plan view. However, the shape of the substrate 2 is not limited to such a case, and, for example, the substrate 2 may be formed in a square shape in plan view.

As one example of the substrate 2, for example, there is a high-resistance silicon (Si) substrate of which a sheet resistance is equal to or higher than 10Ω. In addition, although the resistance value is not limited to 10Ω or more, it is preferable to use a high-resistance substrate of which the sheet resistance is equal to or higher than 10Ω from the point of view of preventing formation of an electrical short circuit between the thermoelectric conversion films 4.

However, the substrate 2 is not limited to a high-resistance silicon substrate and, for example, may be a high-resistance SOI substrate having an oxidant insulation layer inside the substrate, any other high-resistance single-crystal substrate, or a ceramic substrate. In addition, a low-resistance substrate of which sheet resistance is equal to or lower than 10Ω may be used as the substrate 2. In such a case, for example, a high-resistance material may be disposed between the surface of the low-resistance substrate and the thermoelectric conversion film 4.

The substrate 2 is formed with a thickness that is selectively thinned in accordance with a concave part 6 formed in the substrate 2 without the thickness being uniformly formed over the entire face. This will be described later in detail. Here, although the thickness is partly thinned, the substrate 2 has a predetermined rigidity as a whole.

### (Thermoelectric Conversion Film)

The thermoelectric conversion film 4 is formed on the first principal surface 2a of the substrate 2 and includes a plurality of first thermoelectric conversion films 10 and a plurality of second thermoelectric conversion films 11.

The first thermoelectric conversion films 10 and the second thermoelectric conversion films 11 are arranged to be alternately aligned with a fixed gap interposed therebetween along a first direction L1. In this embodiment, the number of first thermoelectric conversion films 10 and the number of second thermoelectric conversion films 11 are the same, and, more specifically, both the numbers thereof are four.

However, the number of first thermoelectric conversion films 10 and the number of second thermoelectric conversion films 11 are not limited to four and, for example, may be appropriately changed in accordance with the overall size, an application, a use environment, and the like of the thermoelectric conversion device 1.

As described above, since the first thermoelectric conversion films 10 and the second thermoelectric conversion films 11 are alternately arranged along the first direction L1, one of the first thermoelectric conversion films 10 is positioned on the outermost side on a one-direction side along the first direction L1, and one of the second thermoelectric conversion films 11 is positioned on the outermost side on the other-direction side along the first direction L1.

In this embodiment, the one-direction side on which one of the first thermoelectric conversion films 10 is positioned on the outermost side will be referred to as a front side, and the other-direction side on which one of the second thermoelectric conversion films 11 is positioned on the outermost side will be referred to as a rear side.

Each of the first thermoelectric conversion films 10 and each of the second thermoelectric conversion films 11 are formed in a rectangular shape that is longer in the second direction L2 than in the first direction L1 in plan view and are formed to have the same shape and the same size. These first thermoelectric conversion films 10 and second thermoelectric conversion films 11, for example, are formed on the first principal surface 2a of the substrate 2 using a sputtering device and thereafter are selectively patterned using etching processing, thereby being formed to be alternately aligned with a constant space interposed therebetween along the first direction L1.

However, a method of forming the first thermoelectric conversion films 10 and the second thermoelectric conversion films 11 is not limited to that of such a case, and any other method may be used for the formation thereof.

The first thermoelectric conversion films 10 and the second thermoelectric conversion films 11 are formed to be semiconductor multilayer films.

More specifically, each first thermoelectric conversion film 10 is formed as a multilayer film of n-type silicon (Si) and an n-type silicon.germanium alloy (SiGe) in which antimony (Sb) of a high density (for example, 10¹⁸ to 10¹⁹ cm⁻³) is doped and functions as an n-type semiconductor. Each second thermoelectric conversion film 11 is formed as a multilayer film of p-type silicon (Si) and a p-type silicon/germanium alloy (SiGe) in which boron (B) of a high density (for example, 10¹⁸ to 10¹⁹ cm⁻³) is doped and functions as a p-type semiconductor.

Accordingly, a current flows from a cold junction side to a hot junction side (in other words, from a side of a second electrode 14 to a side of a first electrode 13 to be described later) in the first thermoelectric conversion film 10 that is the n-type semiconductor, and a current flows from the hot junction side to the cold junction side (in other words, from a side of the first electrode 13 to the second electrode 14 to be described later) in the second thermoelectric conversion film 11 that is the p-type semiconductor.

In addition, a plurality of first thermoelectric conversion films 10 may be either n-type semiconductor multilayer films having the same configuration or n-type semiconductor multilayer films having mutually different configurations. Similarly, a plurality of second thermoelectric conversion films 11 may be either p-type semiconductor multilayer films having the same configuration or p-type semiconductor multilayer films having mutually different configurations.

Furthermore, the first thermoelectric conversion films 10 and the second thermoelectric conversion films 11 are not limited to semiconductor multilayer films and may be single-layer films of p-type or n-type semiconductor. In addition, an oxide semiconductor may be used for the semiconductor. Furthermore, the first thermoelectric conversion films 10 and the second thermoelectric conversion films 11, for example, may be formed using other thermoelectric conversion films such as organic polymer films, metal films, or the like.

### (Electrodes)

A plurality of electrodes 12 each electrically connecting the first thermoelectric conversion film 10 and the second thermoelectric conversion film 11 that are adjacent to each other are formed on the first principal surface 2a of the substrate 2.

Each electrode 12 is disposed between the first thermoelectric conversion film 10 and the second thermoelectric conversion film 11, one of the electrodes 12 is disposed to be positioned further forward of the first thermoelectric conversion film 10 positioned on the front-most side, and one of the electrodes 12 is disposed to be positioned further rearward from the second thermoelectric conversion film 11 positioned on the rearmost side.

The electrode 12 is formed in an oblong shape that is longer in the second direction L2 in plan view and is formed such that a length in the second direction L2 is a length equal to those of the first thermoelectric conversion film 10 and the second thermoelectric conversion film 11.

However, the length of the electrode 12 in the second direction L2 may be longer than or shorter than those of the first thermoelectric conversion film 10 and the second thermoelectric conversion film 11.

The electrode 12 is formed to have a thickness larger than the thicknesses of the first thermoelectric conversion film 10 and the second thermoelectric conversion film 11 and protrudes to the side above the first thermoelectric conversion film 10 and the second thermoelectric conversion film 11.

However, the thickness is not limited to that of such a case, and, for example, the thickness of the electrode 12 may be equal to the thicknesses of the first thermoelectric conversion film 10 and the second thermoelectric conversion film 11 or may be smaller than the thicknesses of the first thermoelectric conversion film 10 and the second thermoelectric conversion film 11.

Among the plurality of electrodes 12, each electrode 12 that is adjacent to the first thermoelectric conversion film 10 and is positioned on the rear side of the first thermoelectric conversion film 10 functions as a first electrode 13. Among the plurality of electrodes 12, the remaining electrodes 12, in other words, each electrode 12 that is adjacent to the first thermoelectric conversion film 10 and is positioned on the front side of the first thermoelectric conversion film 10 functions as a second electrode 14. In addition, the electrode 12 positioned on the rearmost side also functions as the second electrode 14.

Accordingly, a rear end portion 10a of each first thermoelectric conversion film 10 is brought into contact with the first electrode 13 over the entire length in the second direction L2. In addition, a front end portion 10b of each first thermoelectric conversion film 10 is brought into contact with the second electrode 14 over the entire length in the second direction L2.

Similarly, a front end portion 11b of each second thermoelectric conversion film 11 is brought into contact with the first electrode 13 over the entire length in the second direction L2. In addition, a rear end portion 11a of each second thermoelectric conversion film 11 is brought into contact with the second electrode 14 over the entire length in the second direction L2.

Accordingly, the first thermoelectric conversion films 10 and the second thermoelectric conversion films 11 are electrically connected in series through the first electrodes 13 and the second electrodes 14.

In the example illustrated in FIGS. 1 to 3, each first electrode 13 is thermally connected to the first heat transfer plate 3 through a convex part 21 to be described later and has a function of transferring heat from the first heat transfer plate 3 to the rear end portion 10a of the first thermoelectric conversion film 10 and the front end portion 11b of the second thermoelectric conversion film 11. Accordingly, the first electrode 13 functions as a hot junction. On the other hand, the second electrode 14 is positioned in the middle of the first electrodes 13 adjacent to each other in the first direction L1 and functions as a cold junction.

In addition, the rear end portion 10a of the first thermoelectric conversion film 10 and the front end portion 11b of the second thermoelectric conversion film 11 function as an end portion of the hot junction side disposed at positions close to the convex part 21. On the other hand, the front end portion 10b of the first thermoelectric conversion film 10 and the rear end portion 11a of the second thermoelectric conversion film 11 are disposed at positions further away than the end portion (the rear end portion 10a and the front end portion 11b) of the above-described hot junction side in the in-plane direction of the substrate 2 when seen from the convex part 21 and function as an end portion of the cold junction side.

In addition, as a material of the electrode 12, for example, a material which has high conductivity and high thermal conductivity and for which shape processing using patterning can be easily performed is preferable, and a metal material such as copper (Cu), gold (Au), or the like is particularly preferable.

However, the material of the electrode 12 is not particularly limited to a metal material, and the electrode may be formed using a material that is conductive and has thermal conductivity higher than the terminal conductivity of air.

### (Terminal)

A first terminal 15 and a second terminal 16 are further formed on the first principal surface 2a of the substrate 2.

The first terminal 15 is formed to be positioned on a further front side of the second electrode 14 that is positioned on the front-most side and is brought into contact with the second electrode 14 to be electrically connected thereto. The second terminal 16 is formed to be positioned on a further rear side of the second electrode 14 that is positioned on the rear-most side and is brought into contact with the second electrode 14 and is electrically connected thereto.

The first terminal 15 becomes an electrical start end of a thermoelectric conversion circuit composed of the first thermoelectric conversion film 10, the second thermoelectric conversion film 11, the first electrode 13, the second electrode 14, the first terminal 15, and the second terminal 16. On the other hand, the second terminal 16 becomes a terminal end of the thermoelectric conversion circuit described above. The first terminal 15 and the second terminal 16 are electrically connected to an external circuit not illustrated in the drawing. In this way, an electromotive force can be extracted from the thermoelectric conversion device 1 through the first terminal 15 and the second terminal 16.

In addition, as a material of the first terminal 15 and the second terminal 16, for example, a material which has high conductivity and for which shape processing using patterning can be easily performed is preferable, and a metal material such as copper (Cu), gold (Au), or the like is particularly preferable.

However, the material of the first terminal 15 and the second terminal 16 is not limited to a metal material, and the first terminal 15 and the second terminal 16 may be formed using a material having conductivity.

### (First Heat Transfer Plate and Convex Part)

The first heat transfer plate 3 is a member having a flat plate shape, functions as a heat-receiving member in the thermoelectric conversion device 1, and is disposed on the upper side of the substrate 2 with the thermoelectric conversion film 4 interposed therebetween.

The first heat transfer plate 3 is formed in a rectangular shape that is longer in the first direction L1 than in the second direction L2 in plan view in correspondence with the shape of the substrate 2 and is formed to have the same size as that of the external shape of the substrate 2. In addition, an upper face of the first heat transfer plate 3 is formed as a heat-receiving face 20 that is flat over the entire face.

However, the external size of the first heat transfer plate 3 is not limited to that of such a case, and, for example, the first heat transfer plate 3 may be formed in a flat plate shape having a larger external size than the substrate 2 and increase the area of the heat-receiving face 20.

In parts positioned on a further side of a substrate 2 than the first heat transfer plate 3, convex parts (a heat transfer part according to the present disclosure) 21 that are configured to transfer heat from/to the first heat transfer plate 3 and the thermoelectric conversion films 4 are disposed. In the case of this embodiment, the convex parts 21 transfer heat from a side of the first heat transfer plate 3 to a side of the thermoelectric conversion film 4.

The convex parts 21 are formed integrally with the first heat transfer plate 3 and are formed to protrude from the lower face of the first heat transfer plate 3 to the side below, and a plurality of the convex parts 21 are formed with a constant space interposed therebetween in the first direction L1.

More specifically, the convex parts 21 correspond to the number of the first electrodes 13, and four convex parts are formed with spaces interposed therebetween in the first direction L1 and are disposed to face the first electrodes 13 functioning as hot junctions from the upper side. In this way, the second electrodes 14 functioning as cold junctions are positioned in the middle of the convex parts 21 that are adjacent to each other in the first direction L1.

The convex part 21 is formed in an oblong shape that is long in the second direction L2 in plan view in correspondence with the shape of the first electrode 13. More specifically, the convex part 21 is formed to be longitudinally long over the entire length of the first heat transfer plate 3 in the second direction L2 and is formed to be longer than the first electrode 13 in the second direction L2.

However, the length of the convex part 21 in the second direction L2 may be equal to the length of the first electrode 13 or shorter than the first electrode 13.

A lower end face of the convex part 21 is formed to be flat. A width of the convex part 21 in the first direction L1 is equal to a width of the first electrode 13 in the first direction L1. However, the width of the convex part 21 in the first direction L1 may be either larger or smaller than the width of the first electrode 13 in the first direction L1.

The convex part 21 configured as described above is thermally bonded to the first electrode 13 in an electrically insulated state through an insulating member not illustrated in the drawing. In addition, it is preferable to bond the lower end face of the convex part 21 and the upper end face of the first electrode 13 through an insulating member in a state as close to a face contact as possible. In such a case, the thermal bonding described above can be stably performed, and the first heat transfer plate 3 can be stably combined.

In addition, the insulating member is formed using a material having thermal conductivity higher than the thermal conductivity of the air and, for example, there are a UV-curable resin, a silicon-based resin, thermally-conductive grease (for example, silicon-based grease, non-silicon-based grease including a metal oxidant, and the like), and the like as the material of the insulating member.

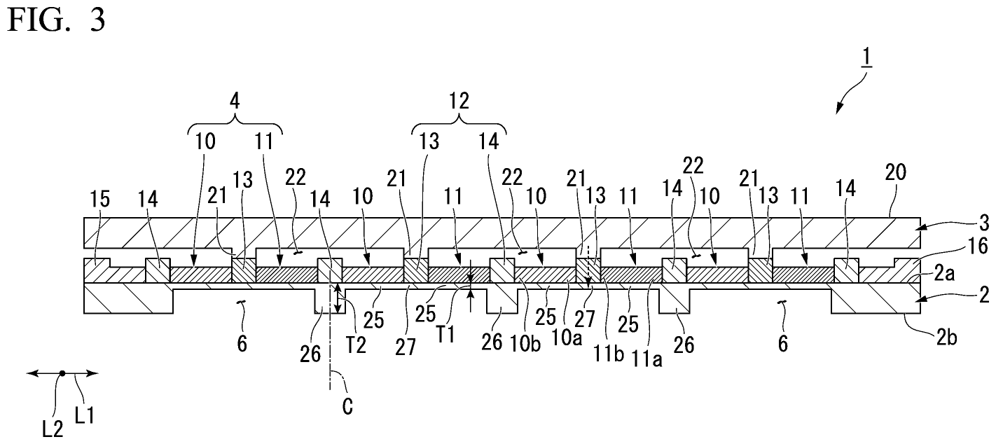

Since the plurality of convex parts 21 are formed on the lower face of the first heat transfer plate 3, an air gap portion (a low heat conduction part according to the present disclosure) 22 is disposed between the convex parts 21 adjacent to each other in the first direction L1. In the example illustrated in FIG. 3, a space between the convex parts 21 that are adjacent to each other in the first direction L1 is formed as a low heat conduction part (the air gap portion 22). The air gap portion 22 is a space between the lower face of the first heat transfer plate 3, the thermoelectric conversion film 4, and the second electrode 14 excluding locations at which the convex parts 21 are formed, in other words, an air layer and has thermal conductivity lower than the thermal conductivity of the convex part 21.

The first heat transfer plate 3 is formed using a material having higher thermal conductivity higher than the thermal conductivity of the air. Accordingly, heat received by the first heat transfer plate 3 through the heat-receiving face 20 is transferred to the first electrodes 13 through the convex parts 21 with priority and can be transferred to the first thermoelectric conversion films 10 and the second thermoelectric conversion films 11 through the first electrode 13. In other words, heat received by the first heat transfer plate 3 is transferred to a side of the thermoelectric conversion film 4 through the convex parts 21 and the first electrode 13 with priority over transfer to a side of the thermoelectric conversion film 4 through the air gap portions 22 without passing through the convex parts 21

In addition, as a material of the first heat transfer plate 3, a material which has higher thermal conductivity than that of the substrate 2 is preferable, and a material which has a further high thermal conductivity and for which processing of a convex shape such as the convex part 21 or the like can be easily processed, for example, a metal material such as aluminum (Al), copper (CU), or the like is particularly preferable.

### (Thickness of Substrate)

As described above, the substrate 2 is not formed to have a uniform thickness over the entire face but is formed such that a thickness thereof is selectively thinned in accordance with concave parts 6. This point will be described in detail.

As illustrated in FIG. 3, a plurality of the above-described concave parts 6 each having a rectangular shape open to a side of the second principal surface 2b in plan view are formed with spaces interposed therebetween in the first direction L1 on the substrate 2. More specifically, the concave parts 6 are formed to be positioned under the first thermoelectric conversion films 10, the second thermoelectric conversion films 11, and the first electrode 13.

Accordingly, a thickness T1 of at least a part of facing portions 25 of the substrate 2 that face the first thermoelectric conversion film 10 and the second thermoelectric conversion film 11 in the thickness direction is smaller than a thickness of at least another part of the substrate 2 other than the facing portions 25 (for example, first parts 26 of the substrate 2 to be described later). In addition, a thickness of a second part 27 of the substrate 2 that faces the convex part 21 and the first electrode 13 in the thickness direction is configured to be the same as the thickness T1 of at least the part of the facing portions 25 described above.

Furthermore, as described above, since the concave parts 6 are formed to be positioned under the first thermoelectric conversion films 10, the second thermoelectric conversion films 11, and the first electrode 13, a thickness T2 of the first part 26 positioned in the middle of the convex parts 21 of the substrate 2, which are adjacent to each other in the first direction L1, in the first direction L1 is larger than the thickness T1 of at least the part of the facing portions 25 described above. In other words, in the example illustrated in FIG. 3, a thickness of the second part 27 of the substrate 2 is smaller than the thickness T2 of the first part 26.

In addition, in the example illustrated in FIG. 3, the first part 26 is positioned on a virtual intermediate line C positioned in the middle of the convex parts 21 that are adjacent to each other in the first direction L1 and is a portion of the substrate 2 that faces the second electrode 14 in the thickness direction.

In addition, the thickness T2 of the first part 26 may be formed to be larger than the thickness T1 of at least the part of the facing portions 25 and, for example, may be smaller than a thickness of a part of the substrate 2 other than the facing portions 25.

### (Operation of Thermoelectric Conversion Device)

Next, the operation of the thermoelectric conversion device 1 configured as described above will be described.

First, in the thermoelectric conversion device 1, thermoelectric conversion is performed using a Seebeck effect of the first thermoelectric conversion film 10 and the second thermoelectric conversion film 11. The following Equation (1) is an equation relating to the Seebeck effect.

E=S×|ΔT| Equation (1)

E(V) in Equation (1) is an electric field (electromotive force) achieved through thermoelectric conversion and, as represented in Equation (1) is defined using a Seebeck coefficient S(V/K) that is a material constant of the first thermoelectric conversion film 10 or the second thermoelectric conversion film 11 and a temperature difference ΔT(K) between the front end portion 10b or 11b and the rear end portion 10a or 11a of the first thermoelectric conversion film 10 or the second thermoelectric conversion film 11.

According to the thermoelectric conversion device 1 of this embodiment, as denoted using a dotted-line arrow illustrated in FIG. 3, heat received by the first heat transfer plate 3 through the heat-receiving face 20 can be transferred to the first electrodes 13 through the convex parts 21 with priority, and heat can be transferred from the first electrode 13 to the rear end portion 10a of the first thermoelectric conversion film 10 and the front end portion 11b of the second thermoelectric conversion film 11.

For this reason, in the first thermoelectric conversion film 10, a temperature difference can be caused to occur between the rear end portion 10a positioned on a side of the first electrode 13 that is a hot junction (an end portion of the hot junction side) and the front end portion 10b positioned on a side of the second electrode 14 that is a cold junction (an end portion of the cold junction side). Similarly, in the second thermoelectric conversion film 11, a temperature difference can be caused to occur between the front end portion 11b positioned on a side of the first electrode 13 that is a hot junction (an end portion of the hot junction side) and the rear end portion 11a positioned on a side of the second electrode 14 that is a cold junction (an end portion of the cold junction side).

Accordingly, an electromotive force based on the Seebeck effect can be generated in each of the first thermoelectric conversion film 10 and the second thermoelectric conversion film 11.

Particularly, since the first thermoelectric conversion film 10 and the second thermoelectric conversion film 11 are electrically connected in series, an electromotive force achieved by summing electromotive forces generated from the first thermoelectric conversion film 10 and the second thermoelectric conversion film 11 can be achieved through the first terminal 15 and the second terminal 16, and an amount of generated power according to the number of thermoelectric conversion films 4 can be achieved.

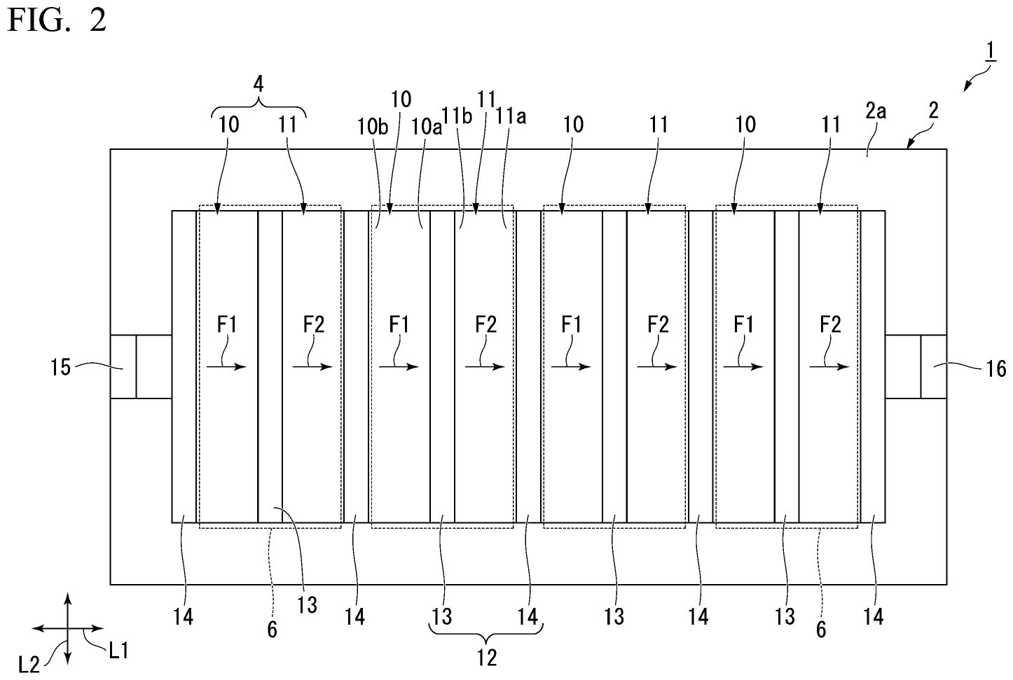

Details of the electromotive force described above will now be described. Since the first thermoelectric conversion film 10 is an n-type semiconductor, a current flows from a side of the second electrode 14 that becomes a cold junction to a side of the first electrode 13 that becomes a hot junction as represented using an arrow F1 illustrated in FIG. 2. On the other hand, since the second thermoelectric conversion film 11 is a p-type semiconductor, a current flows from a side of the first electrode 13 that becomes a hot junction to a side of the second electrode 14 that becomes a cold junction as represented using an arrow F2 illustrated in FIG. 2.

Accordingly, in the first thermoelectric conversion film 10 and the second thermoelectric conversion film 11, electromotive forces of the same direction can be generated, and, as described above, electromotive forces generated in a plurality of first thermoelectric conversion films 10 and a plurality of second thermoelectric conversion films 11 can be extracted through the first terminal 15 and the second terminal 16 as a sum thereof.

Meanwhile, heat transferred from the first heat transfer plate 3 to the first electrodes 13 through the convex parts 21 not only is transferred to the first thermoelectric conversion films 10 and the second thermoelectric conversion films 11 and is moved inside the first thermoelectric conversion films 10 and inside of the second thermoelectric conversion films 11 but also is mainly transferred from the first electrodes 13 to the substrate 2 and is dissipated or cooled through the substrate 2.

At this time, the substrate 2 according to this embodiment is not formed to have a uniform thickness over the entire face unlike a conventional case but has a thickness that is partly changed.

In other words, since the thickness T1 of at least the part of the facing portions 25 of the substrate 2 is formed to be thinner than at least another part of the substrate 2 other than the facing portions 25, heat transferred from the first electrode 13 to the substrate 2 moving from the hot junction side to the cold junction side inside the substrate 2 can be inhibited. In other words, conduction of heat from the hot junction side to the cold junction side inside the substrate 2 can be inhibited by using a change in the thickness of the substrate 2.

Accordingly, a decrease in a temperature difference between the hot junction side and the cold junction side in the first thermoelectric conversion film 10 and the second thermoelectric conversion film 11 due to the influence of conduction of heat through the substrate 2 can be inhibited, whereby a large amount of generated power can be achieved.

As described above, according to the thermoelectric conversion device 1 of this embodiment, a large amount of generated power is achieved using a thickness change in the substrate 2, and the thermoelectric conversion device 1 having high quality and high performance of which thermoelectric conversion efficiency is superior can be configured. In addition, since a simple configuration for only changing the thickness of the substrate 2 is employed, simplification of the configuration of the thermoelectric conversion device 1 is achieved, which can also be linked to weight reduction.

In addition thereto, since the thickness T2 of the first part 26 of the substrate 2 is larger than the thickness T1 of at least the part of the facing portions 25, the end portions of the first thermoelectric conversion film 10 and the second thermoelectric conversion film 11 on the cold junction side, in other words, the front end portion 10b of the first thermoelectric conversion film 10 and the rear end portion 11a of the second thermoelectric conversion film 11 can be cooled with high efficiency in accordance with a heat dissipation or cooling effect at the first parts 26 of the substrate 2.

Accordingly, in the first thermoelectric conversion film 10 and the second thermoelectric conversion film 11, a temperature difference between the hot junction side and the cold junction side can be further increased, whereby a further large amount of generated power can be achieved.

### Modified Example of First Embodiment

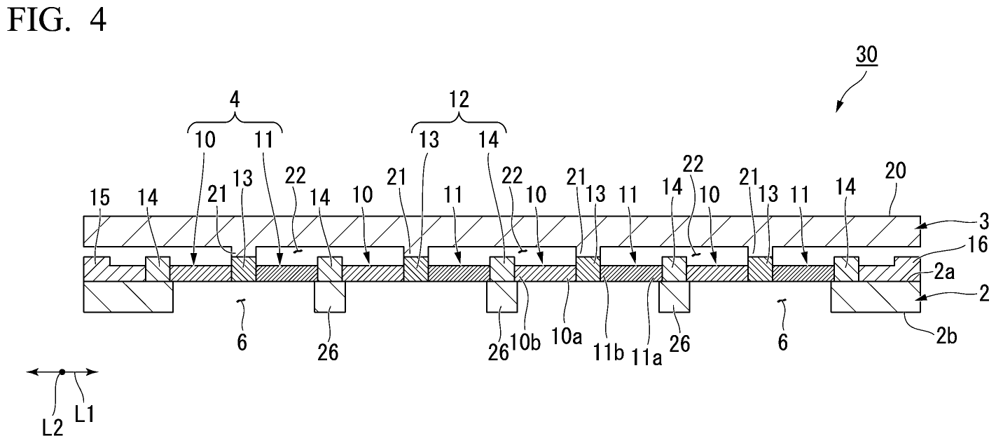

In the first embodiment described above, although both the thickness of at least the part of the facing portions 25 and the thickness of the second parts 27 of the substrate 2 are set to the thickness T1, for example, as illustrated in FIG. 4, by forming concave parts 6 to pass through the substrate 2 in the thickness direction, the substrate 2 may be partly removed. In other words, the facing portions 25 and the second parts 27 of the substrate 2 may be removed.

In the case of the thermoelectric conversion device 30 configured in this way, operations and effects similar to those according to the first embodiment can be successfully achieved more effectively.

In addition, the configuration of forming concave parts 6 to pass through the substrate 2 in the thickness direction may be employed in another embodiment other than the first embodiment.

In the example illustrated in FIG. 4, it is preferable to densely bond the first thermoelectric conversion films 10, the second thermoelectric conversion films 11, the first electrodes 13, and the second electrodes 14, for example, in the in-plane direction of the substrate 2 such that they are combined to have constant rigidity as a whole. In this way, even in a case in which the concave parts 6 are formed to pass through the substrate 2, the first thermoelectric conversion films 10, the second thermoelectric conversion films 11, the first electrodes 13, and the second electrodes 14 can be disposed in a stable state between the substrate 2 and the first heat transfer plate 3.

### Second Embodiment

Next, a thermoelectric conversion device according to a second embodiment of the present disclosure will be described with reference to the drawings.

In the second embodiment, the same reference signs will be assigned to the same parts as the constituent elements of the first embodiment, and description thereof will be omitted.

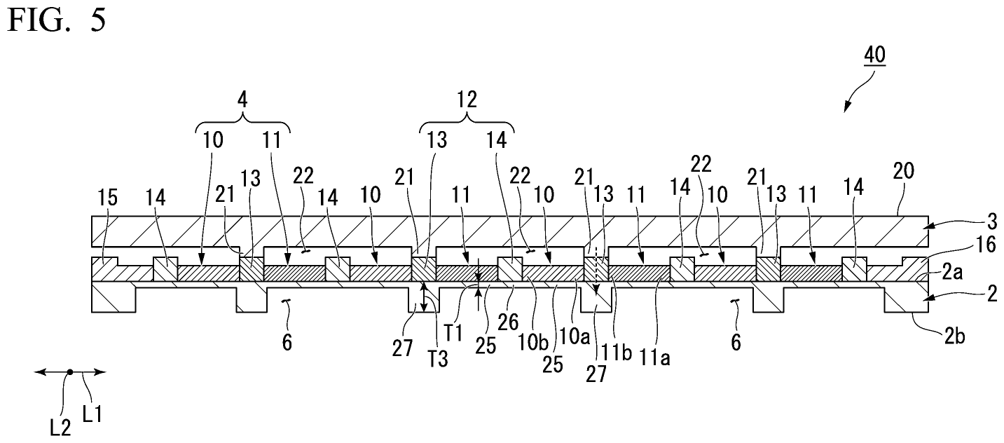

As illustrated in FIG. 5, in a thermoelectric conversion device 40 according to this embodiment, positions of concave parts 6 formed in a substrate 2 are different from those according to the first embodiment. The concave parts 6 according to this embodiment are formed in the substrate 2 such that they are open to a side of a second principal surface 2b of the substrate 2 and are positioned below first thermoelectric conversion films 10, second thermoelectric conversion films 11, and second electrodes 14.

In the thermoelectric conversion device 40 according to this embodiment, the points described above are mainly different from the first embodiment, and the other components are the same as those according to the first embodiment. Furthermore, also in this embodiment, similar to the first embodiment, a case in which heat is transferred from a side of the first heat transfer plate 3 to a side of the thermoelectric conversion film 4 will be described as an example.

Since the concave parts 6 are formed at the positions described above, a thickness of a first part 26 of the substrate 2 is set to a thickness T1 that is the same as a thickness of at least the part of facing portions 25. In addition, a thickness T3 of a second part 27 of the substrate 2 is larger than a thickness T1 of at least the part of the facing portions 25. In addition, in the example illustrated in FIG. 5, the thickness of the first part 26 of the substrate 2 is smaller than a thickness T3 of at least a part of the second part 27.

However, the thickness T3 of the second part 27 may be formed to be larger than the thickness T1 of at least the part of the facing portions 25 and, for example, may be smaller than the thickness of a part of the substrate 2 other than the facing portions 25.

### (Operation of Thermoelectric Conversion Device)

According to the thermoelectric conversion device 40 of this embodiment configured as described above, as represented using a dotted-line arrow illustrated in FIG. 5, heat transferred from convex parts 21 to the substrate 2 through first electrodes 13 can be dissipated or cooled through second parts 27 of the substrate 2 rather than being transferred in the in-plane direction of the substrate 2. Accordingly, conduction of heat from a hot junction side to a cold junction side inside the substrate 2 can be further inhibited.

Accordingly, a temperature difference between the hot junction side and the cold junction side in the first thermoelectric conversion film 10 and the second thermoelectric conversion film 11 can be further increased, and a larger amount of generated power can be achieved.

Particularly, this configuration is effective in a case in which the amount of heat received by the first heat transfer plate 3 is large, and a temperature difference between the hot junction side and the cold junction side in the first thermoelectric conversion film 10 and the second thermoelectric conversion film 11 can be secured while a part of the heat is released to the outside through the second parts 27 of the substrate 2, and a large amount of generated power can be achieved.

### Third Embodiment

Next, a thermoelectric conversion device according to a third embodiment of the present disclosure will be described with reference to the drawings.

In the third embodiment, the same reference signs will be assigned to the same parts as the constituent elements of the first embodiment, and description thereof will be omitted.

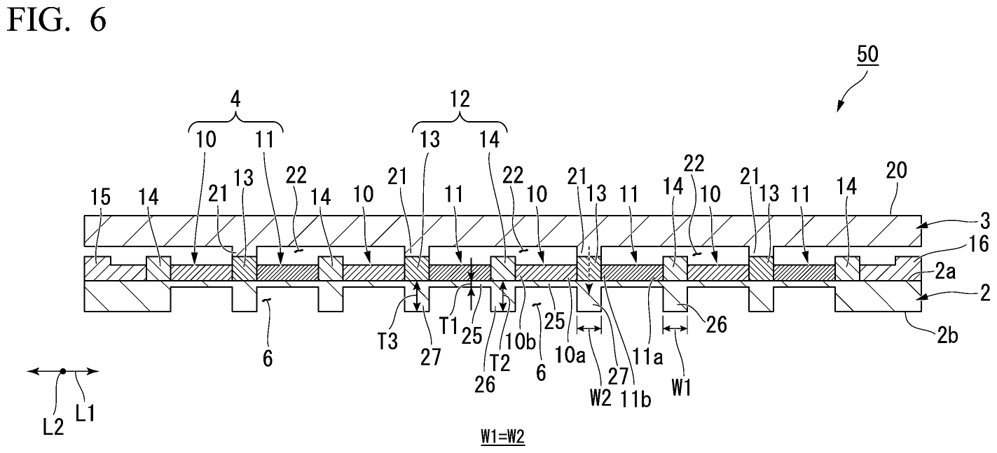

As illustrated in FIG. 6, in a thermoelectric conversion device 50 according to this embodiment, positions of concave parts 6 formed in a substrate 2 are different from those according to the first embodiment. The concave parts 6 according to this embodiment are formed in the substrate 2 such that they are open to a side of a second principal surface 2b of the substrate 2 and are positioned below first thermoelectric conversion films 10 and second thermoelectric conversion films 11.

In the thermoelectric conversion device 50 according to this embodiment, the points described above are mainly different from the first embodiment, and the other components are the same as those according to the first embodiment. Furthermore, also in this embodiment, similar to the first embodiment, a case in which heat is transferred from a side of the first heat transfer plate 3 to a side of the thermoelectric conversion film 4 will be described as an example.

Since the concave parts 6 are formed at the positions described above, a thickness T3 of a second part 27 of the substrate 2 is set to a thickness that is the same as a thickness T2 of a first part 26.

However, the thickness T3 of the second part 27 does not need to be a thickness that is the same as the thickness T2 of the first part 26 and may be either larger or smaller than the thickness T2 of the first part 26 as long as it is larger than a thickness T1 of at least the part of the facing portions 25.

In addition, in this embodiment, a width W1 of the first part 26 in a first direction and a width W2 of the second part 27 in the first direction are configured to be the same.

### (Operation of Thermoelectric Conversion Device)

According to the thermoelectric conversion device 50 of this embodiment configured as described above, similar to the first embodiment, end portions of the first thermoelectric conversion film 10 and the second thermoelectric conversion film 11 on the cold junction side, in other words, the front end portion 10b of the first thermoelectric conversion film 10 and the rear end portion 11a of the second thermoelectric conversion film 11 can be cooled with high efficiency in accordance with a heat dissipation or cooling effect at the first parts 26 of the substrate 2.

In addition, simultaneously with this, similar to the second embodiment, as represented using a dotted-line arrow illustrated in FIG. 6, heat transferred from convex parts 21 to the substrate 2 through first electrodes 13 can be dissipated or cooled through second parts 27 of the substrate 2 rather than being transferred in the in-plane direction of the substrate 2.

In this way, both a heat dissipation or cooling effect using the second parts 27 of the substrate 2 and a heat dissipation or cooling effect using the first parts 26 of the substrate 2 can be used, and accordingly, it is difficult to be influenced by the amount of heat received by the first heat transfer plate 3, and a temperature difference between the hot junction side and the cold junction side in the first thermoelectric conversion film 10 and the second thermoelectric conversion film 11 can be stably increased. Accordingly, a large amount of generated power can be achieved more stably.

### Modified Example of Third Embodiment

In addition, in the third embodiment described above, although a width W1 of the first part 26 of the substrate 2 in a first direction L1 and a width W2 of the second part 27 of the substrate 2 in the first direction L1 are configured to be the same, the widths are not limited to those of such a case and may be appropriately changed.

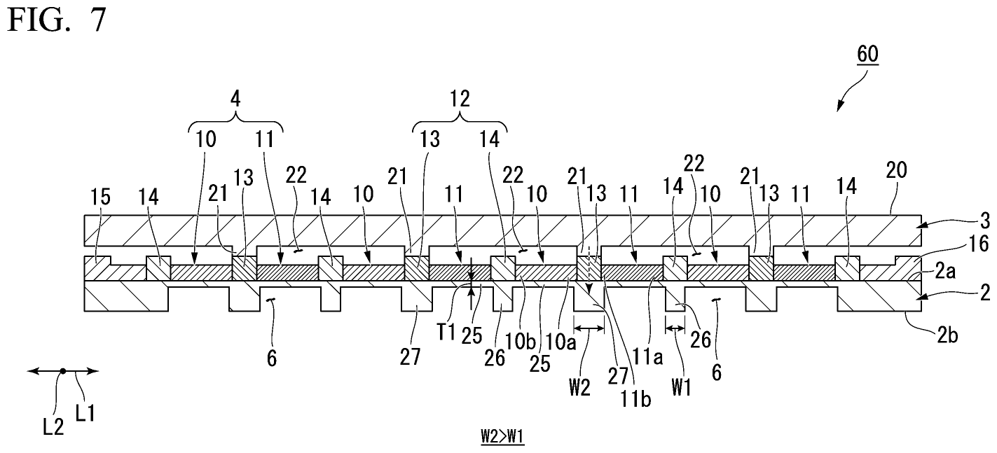

For example, as illustrated in FIG. 7, in the first direction L1, the width W2 of the second part 27 of the substrate 2 in the first direction L1 may be formed to be larger than the width W1 of the first part 26 of the substrate 2 in the first direction L1.

In the thermoelectric conversion device 60 configured in this way, since a heat dissipation or cooling effect using the second parts 27 of the substrate 2 is successfully achieved more effectively than a heat dissipation or cooling effect using the first parts 26 of the substrate 2, for example, in a case in which the amount of heat received by the first heat transfer plate 3 is large, a part of the heat may be easily released quickly to the outside through the second parts 27 of the substrate 2. Accordingly, transfer of a large amount of heat from the hot junction side to the cold junction side inside the substrate 2 can be effectively inhibited.

For this reason, even in a case in which the amount of heat received by the first heat transfer plate 3 is large, it becomes easy to secure a temperature difference between the hot junction side and the cold junction side in the first thermoelectric conversion film 10 and the second thermoelectric conversion film 11, and a large amount of generated power can be achieved.

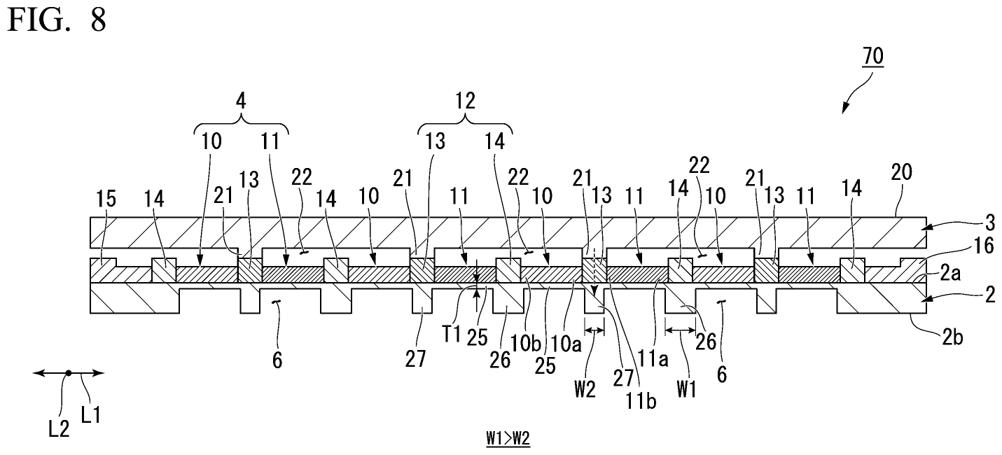

In addition, as illustrated in FIG. 8, in the first direction L1, the width W1 of the first part 26 of the substrate 2 in the first direction L1 may be formed to be larger than the width W2 of the second part 27 of the substrate 2 in the first direction L1.

In the thermoelectric conversion device 70 configured in this way, since a heat dissipation or cooling effect using the first parts 26 of the substrate 2 is successfully achieved more effectively than a heat dissipation or cooling effect using the second parts 27 of the substrate 2, the cold junction side of the first thermoelectric conversion film 10 and the second thermoelectric conversion film 11 (in other words, a side of the front end portion 10b of the first thermoelectric conversion film 10 and a side of the rear end portion 11a of the second thermoelectric conversion film 11) can be easily cooled effectively in accordance with the heat dissipation or cooling effect in the first parts 26 of the substrate 2.

Accordingly, it is easy to secure a temperature difference between the hot junction side and the cold junction side in the first thermoelectric conversion film 10 and the second thermoelectric conversion film 11, and a large amount of generated power can be achieved.

### Fourth Embodiment

Next, a thermoelectric conversion device according to a fourth embodiment of the present disclosure will be described with reference to the drawings.

In the fourth embodiment, the same reference signs will be assigned to the same parts as the constituent elements of the first embodiment, and description thereof will be omitted.

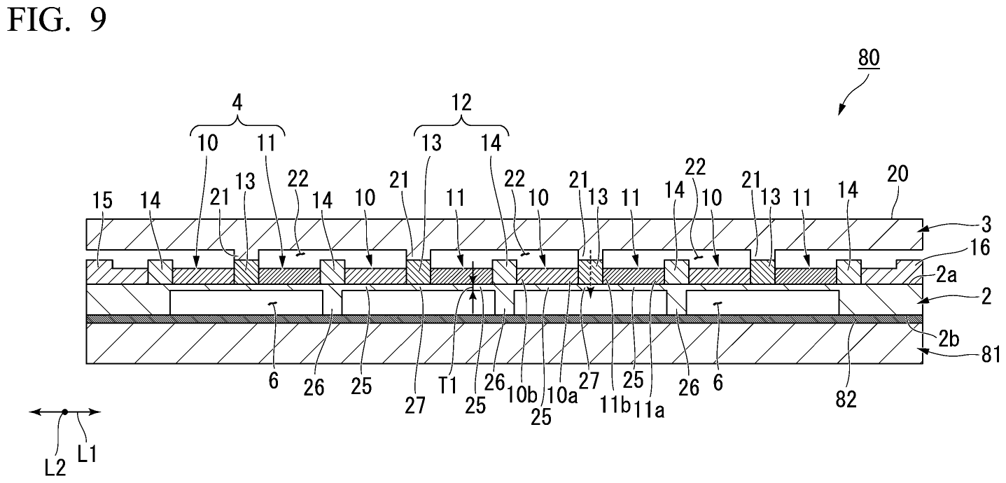

As illustrated in FIG. 9, a thermoelectric conversion device 80 according to this embodiment includes a second heat transfer plate (a second heat transfer member according to the present disclosure) 81 that is disposed on a side of a second principal surface 2b of a substrate 2 and transfers heat to/from the substrate 2.

In the thermoelectric conversion device 80 according to this embodiment, the points described above are mainly different from the first embodiment, and the other components are the same as those according to the first embodiment. Furthermore, also in this embodiment, similar to the first embodiment, a case in which heat is transferred from a side of the first heat transfer plate 3 to a side of the thermoelectric conversion film 4 will be described as an example. For this reason, heat is transferred to the second heat transfer plate 81 through the substrate 2.

The second heat transfer plate 81 is a member having a flat plate shape used for dissipating or cooling heat transferred to the substrate 2 and is formed using a material having higher thermal conductivity than the thermal conductivity of the air. The second heat transfer plate 81 is thermally bonded to first parts 26 of the substrate 2 and transfers heat to/from the first parts 26 rather than facing portions 25. In other words, heat is transferred to the second heat transfer plate 81 through the first parts 26 rather than the facing portions 25.

In addition, in the example illustrated in FIG. 9, the second heat transfer plate 81 is configured to transfer heat from/to the first parts 26 rather than parts interposed between the first parts 26 that are adjacent to each other in the first direction L1 (in other words, the facing portions 25, the second parts 27, and the concave parts 6).

More specifically, the second heat transfer plate 81 is bonded to a second principal surface 2b of the substrate 2 through a paste material 82, thereby being thermally bonded to the first parts 26.

However, the paste material 82 is not essential and thus may not be included. In other words, the second heat transfer plate 81 may be directly bonded to the second principal surface 2b of the substrate 2.

The second heat transfer plate 81 is formed in a rectangular shape longer in the first direction L1 than in the second direction L2 in plan view in correspondence with the shape of the substrate 2 and is formed with the same size as that of the external shape of the substrate 2. In this embodiment, although the external shape of the second heat transfer plate 81 is formed with the same size as that of the substrate 2, the shape is not limited to that of this case, and, for example, the second heat transfer plate 81 may be formed in a flat plate shape having a larger external size than the substrate 2.

It is preferable that the shape of the second heat transfer plate 81 be a shape that is appropriate for heat dissipation or cooling. For example, it is preferable that the second heat transfer plate 81 include a flow passage for air cooling or water cooling inside thereof. In addition, it is preferable that the second heat transfer plate 81, for example, have a pin shape used for heat transfer on a lower face side that is opposite to an upper face bonded to the substrate 2.

It is preferable that a material of the second heat transfer plate 81 be a material having higher thermal conductivity than that of the substrate 2, and a material having particularly high thermal conductivity, for example, a metal material such as aluminum (Al) or copper (Cu) is particularly preferable.

The paste material 82 is formed over the entire face of the upper face of the second heat transfer plate 81 and is disposed between the substrate 2 and the second heat transfer plate 81. Frictional resistance between the substrate 2 and the second heat transfer plate 81 is reduced using the paste material 82.

In addition, as a specific material of the paste material 82, for example, there is heat conductive grease including a highly heat-conductive material such as silver (Ag) or diamond (C) as a filler. In addition, from the point of view of improving thermal conductivity between the substrate 2 and the second heat transfer plate 81, it is preferable that the thermal conductivity of the paste material 82 be higher than the thermal conductivity of the air.

### (Operation of Thermoelectric Conversion Device)

According to the thermoelectric conversion device 80 of this embodiment configured as described above, in addition to operations and effects similar to those according to the first embodiment being successfully achieved, the following operations and effects can be achieved more successfully.

In other words, the cold junction sides of the first thermoelectric conversion film 10 and the second thermoelectric conversion film 11 (in other words, a side of the front end portion 10b of the first thermoelectric conversion film 10 and a side of the rear end portion 11a of the second thermoelectric conversion film 11) can be effectively cooled through the first parts 26 of the substrate 2 using a heat dissipation or cooling effect using a heat dissipation or cooling effect using the second heat transfer plate 81. Accordingly, a temperature difference between the hot junction side and the cold junction side in the first thermoelectric conversion film 10 and the second thermoelectric conversion film 11 can be effectively increased, and a large amount of generated power can be achieved.

### Fifth Embodiment

Next, a thermoelectric conversion device according to a fifth embodiment of the present disclosure will be described with reference to the drawings.

In the fifth embodiment, the same reference signs will be assigned to the same parts as the constituent elements of the second embodiment, and description thereof will be omitted.

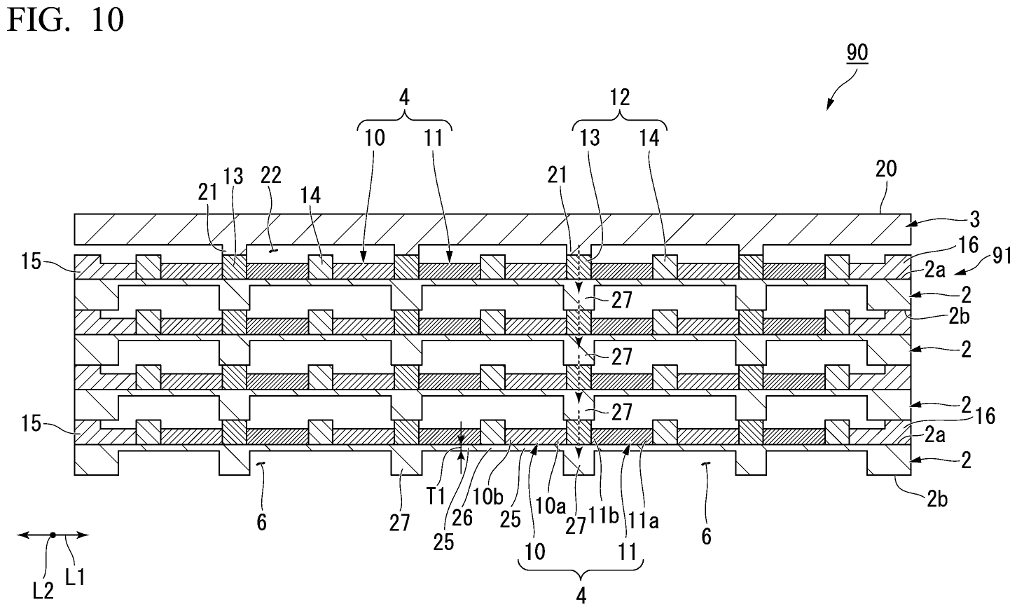

As illustrated in FIG. 10, a thermoelectric conversion device 90 according to this embodiment includes a thermoelectric conversion module 91 in which substrates 2, in which first thermoelectric conversion films 10, second thermoelectric conversion films 11, first electrodes 13, second electrodes 14, a first terminal 15, and a second terminal 16 are disposed on a first principal surface 2a, are piled up in multiple layers in the thickness direction.

In each substrate 2 of the thermoelectric conversion module 91, similar to the second embodiment, concave parts 6 are formed such that they are open to a side of a second principal surface 2b and are positioned under the first thermoelectric conversion film 10, the second thermoelectric conversion film 11, and the second electrode 14.

In the thermoelectric conversion device 90 according to this embodiment, inclusion of the thermoelectric conversion module 91 is mainly different from the second embodiment, and the configurations of the substrate 2, the first thermoelectric conversion films 10, the second thermoelectric conversion film 11, the first electrodes 13, the second electrodes 14, the first terminal 15, and the second terminal 16 are the same as those according to the second embodiment.

Furthermore, in this embodiment, the thermoelectric conversion module 91 is configured such that four layers of substrates 2 are piled up. However, the thermoelectric conversion module 91 is not limited to the structure of four layers and may employ a multi-layer structure in which two or more layers are piled up.

Furthermore, also in this embodiment, similar to the second embodiment, a case in which heat is transferred from a side of the first heat transfer plate 3 to a side of the thermoelectric conversion film 4 positioned on the uppermost (fourth) layer will be described as an example.

The first heat transfer plate 3 is disposed on a side of a first principal surface 2a of the substrate 2 positioned in the uppermost layer (the fourth layer) of the thermoelectric conversion module 91 and is bonded to the first electrodes 13 disposed on the first principal surface 2a of this substrate 2, similar to the second embodiment, through convex parts 21 and an insulating member not illustrated in the drawing.

In the thermoelectric conversion module 91, each substrate 2 positioned in any one of layers other than the uppermost layer (the first layer to the third layer) is disposed such that the first principal surface 2a and the second principal surface 2b face each other with respect to the substrate 2 positioned on a layer above thereof.

In this way, in the thermoelectric conversion module 91, the first electrodes 13 positioned in any one of layers other than the uppermost layer (the first to third layers) are bonded to the second parts 27 of the substrate 2 positioned in a layer above thereof.

In this case, the first electrodes 13 may be bonded to the second parts 27 through other members such as paste materials not illustrated in the drawing.

Accordingly, in the thermoelectric conversion module 91, the thermoelectric conversion films 4 positioned in any one of layers other than the uppermost layer (the first to third layers) are thermally connected to the second parts 27 of the substrate 2 positioned on a layer above thereof through the first electrodes 13 and transfer heat to/from the second parts 27 of the substrate 2 positioned in the layer above thereof rather than the facing portions 25 of the substrate 2 positioned on the layer above thereof. In other words, heat is transferred to the thermoelectric conversion film 4 positioned in any one of layers other than the uppermost layer (the first to third layers) through the second parts 27 of the substrate 2 positioned in the layer above thereof rather than through the facing portions 25 of the substrate 2 positioned in the layer above thereof.

In the example illustrated in FIG. 10, the thermoelectric conversion films 4 positioned in a layer other than the uppermost layer transfer heat to/from the second parts 27 of the substrate 2 positioned on the layer above thereof rather than through portions interposed between the second parts 27, which are adjacent to each other in the first direction L1, (in other words, the facing portions 25, the first parts 26, and the concave parts 6) of the substrate 2 positioned in the layer above thereof.

### (Operation of Thermoelectric Conversion Device)

According to the thermoelectric conversion device 90 of this embodiment configured as described above, in addition to operations and effects similar to those according to the second embodiment being successfully achieved, the following operations and effects can be achieved more successfully.

In other words, since the thermoelectric conversion module 91 is included, for example, heat dissipating through the second parts 27 of the substrate 2 positioned in the fourth layer, as denoted using a dotted-line arrow illustrated in FIG. 10, can be transferred to the first electrodes 13 of the third layer positioned in the layer below thereof and can be transferred to a hot junction side of the first thermoelectric conversion film 10 and the second thermoelectric conversion film 11 positioned in the third layer (in other words, a side of the rear end portion 10a of the first thermoelectric conversion film 10 and a side of the front end portion 11b of the second thermoelectric conversion film 11) through these first electrodes 13.

In this way, dissipated heat can be effectively used, and power generated in the thermoelectric conversion film 4 of each layer can be achieved. Accordingly, a large amount of generated power can be achieved with high efficiency.

### Sixth Embodiment

Next, a thermoelectric conversion device according to a sixth embodiment of the present disclosure will be described with reference to the drawings.

In the sixth embodiment, the same reference signs will be assigned to the same parts as the constituent elements of the third embodiment, and description thereof will be omitted.

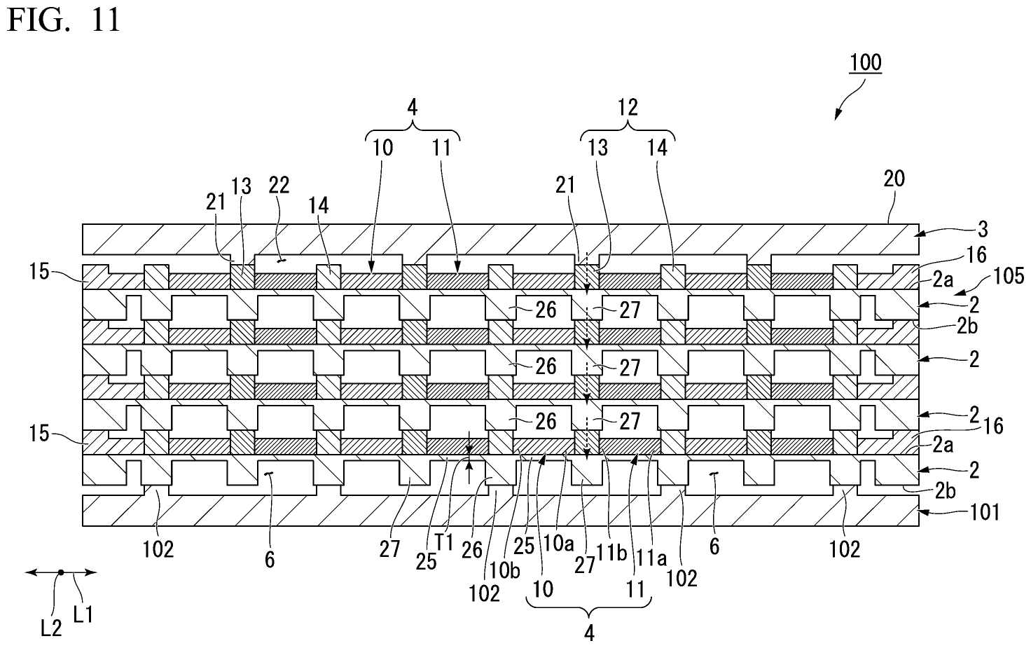

As illustrated in FIG. 11, a thermoelectric conversion device 100 according to this embodiment includes a thermoelectric conversion module 105 in which substrates 2, in which first thermoelectric conversion films 10, second thermoelectric conversion films 11, first electrodes 13, second electrodes 14, a first terminal 15, and a second terminal 16 are disposed on a first principal surface 2a, are piled up in multiple layers in the thickness direction.

In each substrate 2 of the thermoelectric conversion module 105, similar to the third embodiment, concave parts 6 are formed such that they are open to a side of a second principal surface 2b and are positioned under the first thermoelectric conversion film 10 and the second thermoelectric conversion film 11.

In the thermoelectric conversion device 100 according to this embodiment, inclusion of the thermoelectric conversion module 105 is mainly different from the third embodiment, and the configurations of the substrate 2, the first thermoelectric conversion films 10, the second thermoelectric conversion film 11, the first electrodes 13, the second electrodes 14, the first terminal 15, and the second terminal 16 are the same as those according to the third embodiment.

Furthermore, in this embodiment, the thermoelectric conversion module 105 is configured such that four layers of substrates 2 are piled up. However, the thermoelectric conversion module 105 is not limited to the structure of four layers and may employ a multi-layer structure in which two or more layers are piled up.

Furthermore, also in this embodiment, similar to the third embodiment, a case in which heat is transferred from a side of the first heat transfer plate 3 to a side of the thermoelectric conversion film 4 positioned on the uppermost (fourth) layer will be described as an example.

The thermoelectric conversion device 100 according to this embodiment includes a second heat transfer plate (a second heat transfer member according to the present disclosure) 101 that is disposed on a side of a second principal surface 2b of the substrate 2 positioned in the lowermost layer (first layer) in thermoelectric conversion module 105 and transfers heat to/from this substrate 2. In other words, heat is transferred to the second heat transfer plate 101 through the substrate 2 positioned in the lowermost layer.

The first heat transfer plate 3 is disposed on a side of a first principal surface 2a of the substrate 2 positioned in the uppermost layer (the fourth layer) of the thermoelectric conversion module 105 and is bonded to the first electrodes 13 disposed on the first principal surface 2a of this substrate 2, similar to the third embodiment, through convex parts 21 and an insulating member not illustrated in the drawing.

In the thermoelectric conversion module 105, the first electrodes 13 positioned in any one of layers other than the uppermost layer (the first to third layers) are bonded to the second parts 27 of the substrate 2 positioned in the layer above thereof, and the second electrodes 14 positioned in any one of layers other than the uppermost layer (the first to third layers) are bonded to the first parts 26 of the substrate 2 positioned in the layer above thereof. In this case, the first electrodes 13 may be bonded to the second parts 27 through other members such as paste materials not illustrated in the drawing. Similarly, the second electrodes 14 may be bonded to the first parts 26 through other members such as paste materials not illustrated in the drawing.

Accordingly, in the thermoelectric conversion module 105, the thermoelectric conversion films 4 positioned in any one of layers other than the uppermost layer (the first to third layers) are thermally bonded to the second parts 27 of the substrate 2 positioned in a layer above thereof through the first electrode 13 and transfer heat to/from the second parts 27 of the substrate 2 positioned in the layer above thereof rather than the facing portions 25 of the substrates 2 positioned in the layer above thereof. In other words, heat is transferred to the thermoelectric conversion films 4 positioned in any one of layers other than the uppermost layer (the first to third layers) through the second parts 27 of the substrate 2 positioned in a layer above thereof rather than through the facing portions 25 of the substrate 2 positioned in the layer above thereof.

In addition, the thermoelectric conversion films 4 positioned in any one of layers other than the uppermost layer (the first to third layers) are thermally bonded to the first parts 26 of the substrate 2 positioned in a layer above thereof through the second electrodes 14 and transfer heat to/from the first parts 26 of the substrate 2 positioned in the layer above thereof rather than through the facing portions 25 of the substrate 2 positioned on the layer above thereof. In other words, heat is transferred to the thermoelectric conversion films 4 positioned in any one of layers other than the uppermost layer (the first to third layers) through the first parts 26 of the substrate 2 positioned in the layer above thereof rather than through the facing portions 25 of the substrate 2 positioned in the layer above thereof.

The second heat transfer plate 101 is a member having a flat plate shape used for dissipating or cooling heat transferred to the substrate 2 positioned in the lowermost layer (the first layer), is formed using a material having higher thermal conductivity than the thermal conductivity of the air, is thermally bonded to the first parts 26 of the substrate 2 positioned in the first layer through convex parts 102 to be described later, and transfers heat to/from the first parts 26 of the substrate 2 positioned in the first layer rather than to/from the facing portions 25 of the substrate 2 positioned in the first layer. In other words, heat is transferred to the second heat transfer plate 101 through the first parts 26 of the substrate 2 positioned in the first layer rather than the facing portions 25 of the substrate 2 positioned in the first layer.

In addition, the second heat transfer plate 101 is bonded to the first parts 26 of the substrate 2 positioned in the first layer from the lower side through convex parts 102 to be described later in a state not contacting with the second parts 27 of the substrate 2 positioned in the first layer. Accordingly, the second heat transfer plate 101 is thermally bonded to the first parts 26 of the substrate 2 positioned in the first layer and transfers heat to/from the first parts 26 of the substrate 2 positioned in the first layer rather than the second parts 27 of the substrate 2 positioned in the first layer. In other words, heat is transferred to the second heat transfer plate 101 through the first parts 26 of the substrate 2 positioned in the first layer rather than through the second parts 27 of the substrate 2 positioned in the first layer. In other words, in the example illustrated in FIG. 11, the second heat transfer plate 101 transfers heat to/from the first parts 26 of the substrate 2 positioned in the first layer rather than parts interposed between the first parts 26, which are adjacent to each other in the first direction L1, of the substrate 2 positioned in the first layer (in other words, the facing portions 25, the second parts 27, and the concave parts 6).

In this embodiment, a plurality of convex parts 102 are formed integrally with the second heat transfer plate 101 on the upper face of the second heat transfer plate 101.

The convex parts 102 protrude to the upper side from the upper face of the second heat transfer plate 101 and are disposed with a constant space interposed therebetween in the first direction L1.

More specifically, the convex parts 102 are formed in correspondence with the first parts 26 of the substrate 2 positioned in the first layer and are disposed to face these first parts 26 from the lower side. By bonding these convex parts 102 to the first parts 26 of the substrate 2, the second heat transfer plate 101 is combined to the substrate 2 positioned in the first layer.

In the example illustrated in FIG. 11, although the convex parts 102 are directly bonded to the first parts 26, the convex parts 102, similar to the second heat transfer plate 81 according to the fourth embodiment, may be bonded to the first parts 26 through other members such as paste materials or the like.

As described above, since a plurality of the convex parts 102 are formed on the upper face of the second heat transfer plate 101, a gap (an air layer) is secured in the thickness direction between a lower face (a lower face except for positions at which the convex parts 102 are formed) of the substrate 2 positioned in the first layer and the second heat transfer plate 101. Accordingly, as described above, the second heat transfer plate 101 is in a state not contacting with the second parts 27.

In addition, also in this embodiment, similar to the fourth embodiment, a shape that is appropriate for heat dissipation or cooling is preferable as the shape of the second heat transfer plate 101. In addition, as a material of the second heat transfer plate 101, a material having higher thermal conductivity than that of the substrate 2 is preferable, and a material particularly having high thermal conductivity, for example, a metal material such as aluminum (Al), copper (Cu), or the like is particularly preferable.

### (Operation of Thermoelectric Conversion Device)

According to the thermoelectric conversion device 100 of this embodiment configured as described above, in addition to operations and effects similar to those according to the third embodiment being successfully achieved, the following operations and effects can be achieved more successfully.

In other words, since the thermoelectric conversion module 105 is included, for example, heat dissipating through the second parts 27 of the substrate 2 positioned in the fourth layer, as denoted using a dotted-line arrow illustrated in FIG. 11, can be transferred to the first electrodes 13 of the third layer positioned in the layer below thereof and can be transferred to a hot junction side of the first thermoelectric conversion film 10 and the second thermoelectric conversion film 11 positioned in the third layer (in other words, a side of the rear end portion 10a of the first thermoelectric conversion film 10 and a side of the front end portion 11b of the second thermoelectric conversion film 11) through these first electrodes 13.

In this way, dissipated heat can be effectively used, and power generated in the thermoelectric conversion film 4 of each layer can be achieved. Accordingly, a large amount of generated power can be achieved with high efficiency.

In addition, the cold junction side of the first thermoelectric conversion films 10 and the second thermoelectric conversion films 11 of each layer (in other words, the front end portion 10b of the first thermoelectric conversion film 10 and the rear end portion 11a of the second thermoelectric conversion film 11) can be cooled with high efficiency through the first parts 26 of the substrate 2 of each layer. Accordingly, in the first thermoelectric conversion films 10 and the second thermoelectric conversion films 11 in each layer, a temperature difference between the hot junction side and the cold junction side can be effectively increased, and a large amount of generated power can be achieved.

Particularly, by using the cooling effect using the second heat transfer plate 101, the cold junction sides of the first thermoelectric conversion film 10 and the second thermoelectric conversion film 11 (in other words, a side of the front end portion 10b of the first thermoelectric conversion film 10 and a side of the rear end portion 11a of the second thermoelectric conversion film 11) can be effectively cooled through the first parts 26 of the substrate 2 positioned in the first layer. Accordingly, as a result, in the first thermoelectric conversion film 10 and the second thermoelectric conversion film 11 of each layer, a temperature difference between the hot junction side and the cold junction side can be effectively increased.

In addition, in this embodiment, although a case in which the second heat transfer plate 101 is included has been described as an example, the second heat transfer plate 101 is not an essential component and thus may not be included.

### Modified Example of Sixth Embodiment

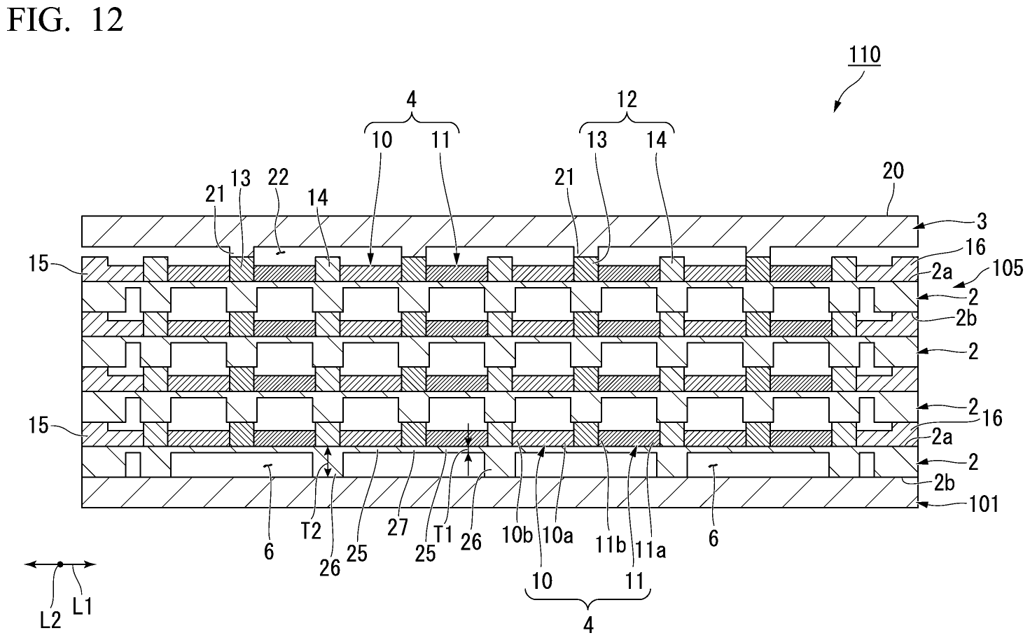

In the sixth embodiment described above, although the convex parts 102 are arranged in the second heat transfer plate 101, the convex parts 102 are not essential and thus may not be included. For example, as illustrated in FIG. 12, a thermoelectric conversion device 110 including a second heat transfer plate 101 formed in a flat panel shape may be configured.

In such a case, in the substrate 2 positioned in the first layer, the thickness of the second part 27 may be configured to be smaller than the thickness T2 of the first part 26. In such a case, heat is transferred to the second heat transfer plate 101 through the first parts 26 of the substrate 2 positioned in the first layer rather than through the second parts 27 of the substrate 2 positioned in the first layer.

Also in the case of the thermoelectric conversion device 110 configured in this way, operations and effects similar to those according to the sixth embodiment can be successfully achieved. In addition thereto, in accordance with no formation of convex parts 102 in the second heat transfer plate 101, the entire thermoelectric conversion device 110 can be thinly formed.

As above, while the embodiments of the present disclosure have been described, such embodiments are presented as examples and are not intended to limit the scope of the disclosure. Each embodiment can be performed in other various forms, and, in a range not departing from the concept of the disclosure, various omissions, substitutions, and changes can be performed, and modified examples of each embodiment may be appropriately combined. In addition, these embodiments and the modified examples thereof, for example, include elements that can be easily conceived by a person skilled in the art, elements that are the substantially the same, elements included in an equivalent range, and the like.

For example, in each embodiment described above, although each of the first heat transfer plates 3 and the second heat transfer plates 81 and 101 is formed in one flat plate shape formed with the same shape and the same size as those of the substrate 2, the configuration is not limited to such a case, and each thereof may be formed using a plurality of members.

In addition, in each embodiment described above, although the thermoelectric conversion film 4 has been described as an example of a thermoelectric conversion elements, the thermoelectric conversion elements are not limited to a film and, for example, may be a bulk thermoelectric conversion element or the like.

In addition, in each embodiment described above, although the convex parts 21 formed integrally with the first heat transfer plate 3 have been described as heat transfer parts as an example, the convex parts 21 do not need to be formed integrally with the first heat transfer plate 3. For example, the first heat transfer plate 3 may be formed in a flat plate shape, and convex parts that are separate from the first heat transfer plate 3 may be disposed between the first heat transfer plate 3 and the first electrodes 13. In such a case, for example, the convex parts can be formed using a different material from that of the first heat transfer plate 3, and accordingly, the degree of freedom in selection of a material can be improved.

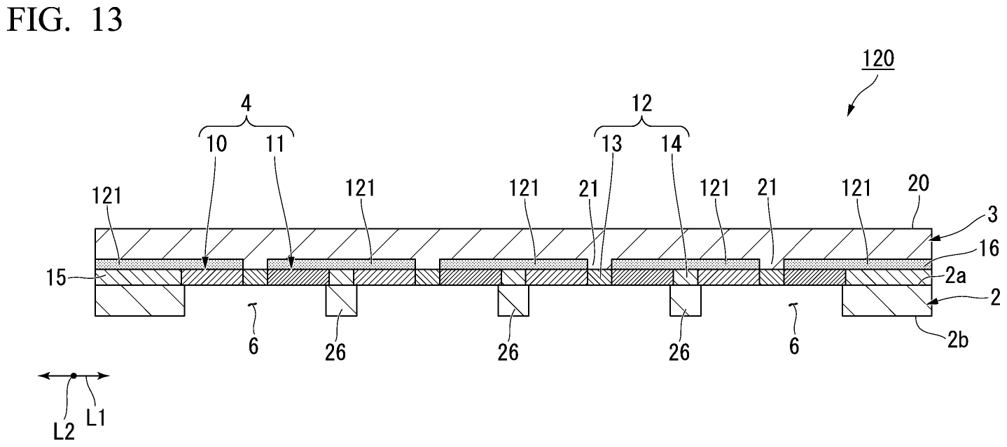

In addition, in each embodiment described above, although the gap portion 22 that is an air layer, of which thermal conductivity is lower than the thermal conductivity of the convex part 21, is formed between the convex parts 21 adjacent to each other in the first direction L1, in other words, the air gap portion 22 that is an air layer is formed between the lower face of the first heat transfer plate 3 except for positions at which the convex parts 21 are formed, the thermoelectric conversion film 4, and the second electrode 14, the present disclosure is not limited to such a case. For example, as illustrated in FIG. 13, a thermoelectric conversion device 120 in which low heat conduction members 121 having lower thermal conductivity than the convex part 21 as low heat conduction parts are formed on the lower face side of the first heat transfer plate 3 to replace the air gap portions 22 that are air layers may be configured. As a material of the low heat conduction members 121, for example, aluminum oxide (Al₂O₃), polytetrafluoroethylene (PTFE), a polyimide resin, or the like may be used.

Also in such a case, heat received by the first heat transfer plate 3 can be transferred to the first electrodes 13 through the convex parts 21 with priority, and heat can be transferred from the first electrodes 13 to an end portion of the thermoelectric conversion film 4 on the hot junction side.

In addition, in the example illustrated in FIG. 13, the thickness of each of the first electrode 13, the second electrode 14, the first terminal 15, and the second terminal 16 is the same as that of the thermoelectric conversion film 4. Accordingly, the thickness of the entire thermoelectric conversion device 120, for example, can be thinned more than that of the case according to the first embodiment, and thinning and compactification of the thermoelectric conversion device can be achieved. Furthermore, in the example illustrated in FIG. 13, a case in which concave parts 6 are formed to pass through the substrate 2 in the thickness direction is illustrated as an example.

In addition, in each embodiment described above, heat transfer parts are not limited to the convex parts 21. For example, upper end faces of the first electrodes 13 may be brought into contact with the lower face of the first heat transfer plate 3 formed in a flat plate shape by causing the first electrodes 13 to protrude to the upper side from the thermoelectric conversion films 4, the second electrodes 14, the first terminals 15, and the second terminals 16.

Also in such a case, heat received by the first heat transfer plate 3 can be transferred to the first electrodes 13 with priority, and heat can be transferred from the first electrodes 13 to end portions of the thermoelectric conversion films 4 on the hot junction side. Accordingly, in this case, the first electrodes 13 can function as heat transfer parts.

The heat transfer parts may transfer heat to/from the thermoelectric conversion films 4 through the heat transfer parts with priority rather than transferring heat to/from the thermoelectric conversion films 4 without passing through the heat transfer parts and may employ various configurations.

In addition, in each embodiment described above, the first electrodes 13 and the second electrodes 14 are not essential and thus may not be included.

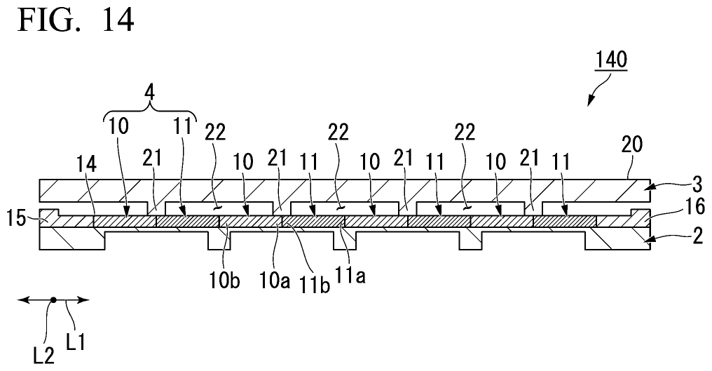

For example, in a thermoelectric conversion device 140 illustrated in FIG. 14, first thermoelectric conversion films 10 and second thermoelectric conversion films 11 are alternately disposed on a first principal surface 2a of the substrate 2 in the first direction L1, and each of the first thermoelectric conversion films 10 and each of the second thermoelectric conversion films 11 are formed to be in contact with each other. Convex parts 21 formed integrally with the first heat transfer plate 3 are disposed to be bonded to the rear end portion 10a of the first thermoelectric conversion film 10 and the front end portion 11b of the second thermoelectric conversion film 11, for example, similar to the first embodiment, through insulating members.

Also in such a case, for example, the operations and effects similar to those according to the first embodiment can be successfully achieved.

In addition, in each embodiment described above, although the thermoelectric conversion film 4 is composed of the first thermoelectric conversion film 10 that is an n-type semiconductor and the second thermoelectric conversion film 11 that is a p-type semiconductor, the configuration is not limited to that of such a case, and a thermoelectric conversion film formed by any one of the n-type semiconductor and the p-type semiconductor may be used.

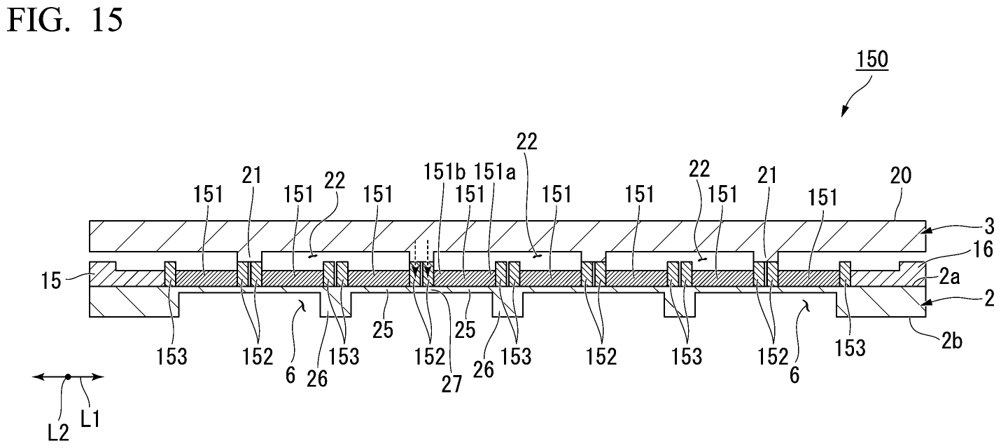

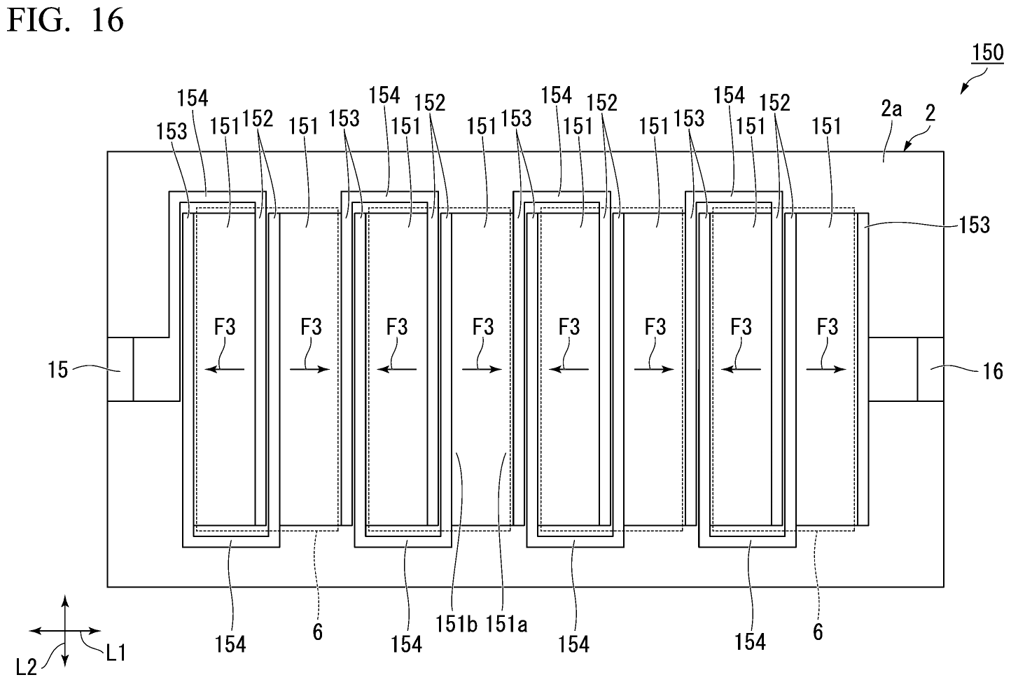

For example, a thermoelectric conversion device 150 illustrated in FIGS. 15 and 16 includes a plurality of thermoelectric conversion films (thermoelectric conversion elements according to the present disclosure) 151 that are p-type semiconductors formed on a first principal surface 2a of a substrate 2. In addition, the thermoelectric conversion films 151 may be n-type semiconductors.

The thermoelectric conversion films 151 are disposed to be aligned with a constant space interposed therebetween in the first direction L1. The thermoelectric conversion films 151, for example, similar to the first embodiment, are formed in a rectangular shape that is longer in the second direction L2 than in the first direction L1 in plan view.

A plurality of first electrodes 152 functioning as hot junctions and a plurality of second electrodes 153 functioning as cold junctions are formed on the first principal surface 2a of the substrate 2. The first electrode 152 and the second electrode 153 are disposed for each thermoelectric conversion film 151.

More specifically, the first electrode 152 and the second electrode 153 are disposed on a side of the front end portion 151b or a side of the rear end portion 151a of the thermoelectric conversion film 151 to have the thermoelectric conversion film 151 interposed therebetween in the first direction L1 and are brought into contact with the thermoelectric conversion film 151. The first electrode 152 and the second electrode 153 are formed over the entire length of the thermoelectric conversion film 151 in the second direction L2.

The first electrode 152 disposed in each thermoelectric conversion film 151 is formed such that it is disposed under the convex part 21. Accordingly, in a relationship between thermoelectric conversion films 151 adjacent to each other in the first direction L1, the first electrodes 152 and the second electrodes 153 that are respectively bonded together are adjacently disposed with a slight gap interposed therebetween in the first direction L1.

On the first principal surface 2a of the substrate 2, a connection electrode 154, a first terminal 15, and a second terminal 16 are further formed.

In the thermoelectric conversion films 151 adjacent to each other in the first direction L1, the connection electrode 154 is formed to be connected to the first electrode 152 disposed in one thermoelectric conversion film 151 and the second electrode 153 disposed in the other thermoelectric conversion film 151. The connection electrode 154 is formed to wrap around the thermoelectric conversion film 151 from the outer side of the second direction L2.

The first terminal 15 is formed to be positioned on a further front side of the second electrode 153 disposed in the thermoelectric conversion film 151 positioned on the front-most side and is connected to the first electrode 152 disposed in the thermoelectric conversion film 151 positioned on the front-most side through the connection electrode 154. The second terminal 16 is formed to be positioned on a further rear side of the second electrode 153 disposed in the thermoelectric conversion film 151 positioned in the rear-most side and is brought into contact with the second electrode 153.

In this way, the thermoelectric conversion films 151 can be electrically connected in series through the connection electrode 154, and an electromotive force can be extracted from the thermoelectric conversion device 150 through the first terminal 15 and the second terminal 16.

Also in the case of the thermoelectric conversion device 150 configured in this way, for example, only a method of causing a current to flow through the thermoelectric conversion film 151 is different from that according to the first embodiment, and similar operations and effects can be successfully achieved.

More specifically, as denoted using a dotted-line arrow illustrated in FIG. 15, heat received by the first heat transfer plate 3 through a heat-receiving face 20 can be transferred to the first electrodes 152 through the convex parts 21 with priority, and heat can be transferred from the first electrodes 152 to the front end portions 151b or the rear end portions 151a of the thermoelectric conversion film 151 (end portions of the thermoelectric conversion films 151 on the hot junction side). Since the thermoelectric conversion film 151 is a p-type semiconductor, a current as denoted using an arrow F3 illustrated in FIG. 16 flows from a side of the first electrode 152 that is a hot junction to a side of the second electrode 153 that is a cold junction.

At this time, since the connection electrode 154 is formed, as a result, an electromotive force in the same direction can be generated in each thermoelectric conversion film 151, and the electromotive force generated in each thermoelectric conversion film 151 can be extracted as a total electromotive force through the first terminal 15 and the second terminal 16.

Accordingly, also in the case of the thermoelectric conversion device 150 illustrated in FIGS. 15 and 16, operations and effects similar to those according to the first embodiment can be successfully achieved.

In addition, in each embodiment described above, although a case in which the first heat transfer plate 3 is included has been described as an example, the first heat transfer plate 3 is not an essential configuration and thus may not be included.

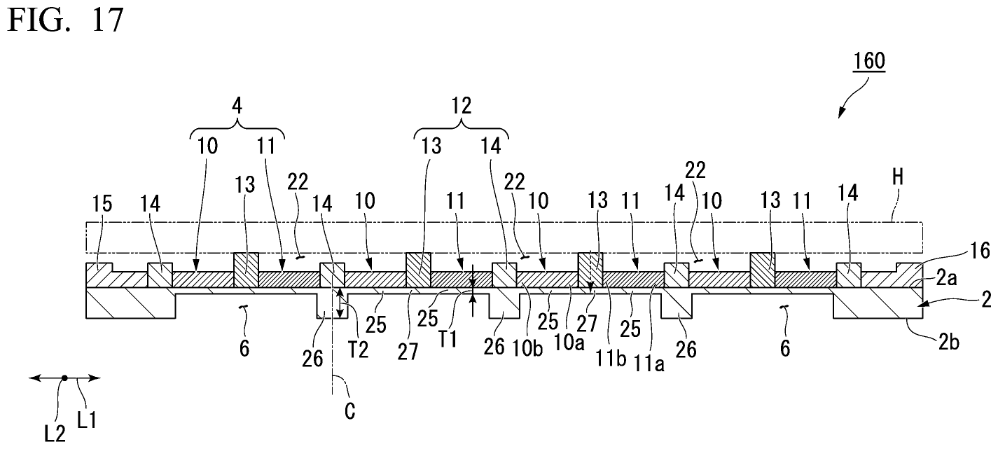

For example, as illustrated in FIG. 17, a thermoelectric conversion device 160 having a configuration achieved by omitting the first heat transfer plate 3 from the first embodiment may be used. In addition, in the form illustrated in FIG. 17, the same reference signs are assigned to the same parts as constituent elements according to the first embodiment, and description thereof will be omitted.

In addition to no inclusion of the first heat transfer plate 3, the thermoelectric conversion device 160 causes first electrodes 13 to function as heat transfer parts, which is different from the first embodiment. The other components are similar to those according to the first embodiment.

In this thermoelectric conversion device 160, the first electrodes 13 protrude to the upper side from thermoelectric conversion films 4, second electrodes 14, a first terminal 15, and a second terminal 16. An upper end face of the first electrode 13 is thermally bonded to a heat source H. Accordingly, heat from the heat source H can be transferred to an end portion of the thermoelectric conversion film 4 on the hot junction side, in other words, a rear end portion 10a of a first thermoelectric conversion film 10 and a front end portion 11b of the second thermoelectric conversion film 11 with priority through the first electrodes 13.

Accordingly, also in the case of the thermoelectric conversion device 160 configured as such, operations and effects similar to those according to the first embodiment can be successfully achieved. Particularly, in accordance with no inclusion of the first heat transfer plate 3, the entire thickness of the thermoelectric conversion device 160 can be configured to be thinner than that according to the first embodiment, and it is easy to achieve thinning and compactification.

In addition, although one example of the thermoelectric conversion device 160 not including the first heat transfer plate 3 using the first embodiment as a base has been described with reference to FIG. 17, a configuration not including the first heat transfer plate 3 in any other embodiments may be employed.

Furthermore, in each embodiment described above, although a case in which heat is transferred from a side of the first heat transfer plate 3 to a side of the thermoelectric conversion film 4 has been described as an example, the present disclosure is not limited to such a case, and, as described above, a case in which heat is transferred from a side of the substrate 2 to a side of the thermoelectric conversion film 4 may be employed.

For example, brief description will be given using the thermoelectric conversion device 1 according to the first embodiment illustrated in FIGS. 1 to 3 as an example.

In the thermoelectric conversion device 1, for example, in a case in which a heat source not illustrated in the drawing is present on the substrate side, and heat is received by the substrate 2 from the heat source, heat is transferred from a side of the substrate 2 to a side of the thermoelectric conversion elements 4, and heat dissipation or cooling is performed through the first heat transfer plate 3. At this time, as described in the first embodiment, since the thickness T1 of at least the part of the facing portions 25 of the substrate 2 is formed to be thinner than at least another part of the substrate 2 other than the facing portions 25, movement of heat, which has been transferred from the heat source to the substrate 2, from the hot junction side to the cold junction side inside the substrate 2 can be inhibited.

Accordingly, by using a change in the thickness of the substrate 2, a decrease in a temperature difference occurring between the hot junction side and the cold junction side of the thermoelectric conversion elements 4 due to the influence of conduction of heat through the substrate 2 can be inhibited, and a large amount of generated power can be achieved.

For this reason, also in a case in which heat is transferred from a side of the substrate 2 to a side of the thermoelectric conversion film 4, operations and effects similar to those of a case in which heat is transferred from the first heat transfer plate 3 to a side of the thermoelectric conversion film 4 are successfully achieved.

In addition, in the thermoelectric conversion device 1 of this case, since heat from the substrate 2 can be easily transferred to the second electrodes 14 through the first parts 26, the second electrodes 14 function as hot junctions, and the first electrodes 13 function as cold junctions. For this reason, the rear end portion 10a of the first thermoelectric conversion film 10 and the front end portion 11b of the second thermoelectric conversion film 11 function as end portions of the cold junction side, and the front end portion 10b of the first thermoelectric conversion film 10 and the rear end portion 11a of the second thermoelectric conversion film 11 function as an end portion of the hot junction side.

However, also in this case, since the thickness T1 of at least the part of the facing portions 25 of the substrate 2 is formed thinner than at least another part of the substrate 2 other than the facing portions 25 as described above, transfer of heat, which has been transferred from the heat source to the substrate 2, from the hot junction side to the cold junction side inside the substrate 2 can be inhibited. Accordingly, a temperature difference between the hot junction side and the cold junction side in the thermoelectric conversion elements 4 can be increased, and a large amount of generated power can be achieved.

In addition, since the first heat transfer plate 3, for example, can be caused to function as a heat dissipation or cooling member or the like, by using a heat dissipation or cooling effect using the first heat transfer plate 3, heat transferred to the substrate 2 can be dissipated or cooled through the convex parts 21 and the first heat transfer plate 3 rather than being transferred in the in-plane direction of the substrate 2. Accordingly, a temperature difference between the hot junction side and the cold junction side in the thermoelectric conversion elements 4 can be effectively increased, and a large amount of generated power is easily achieved.

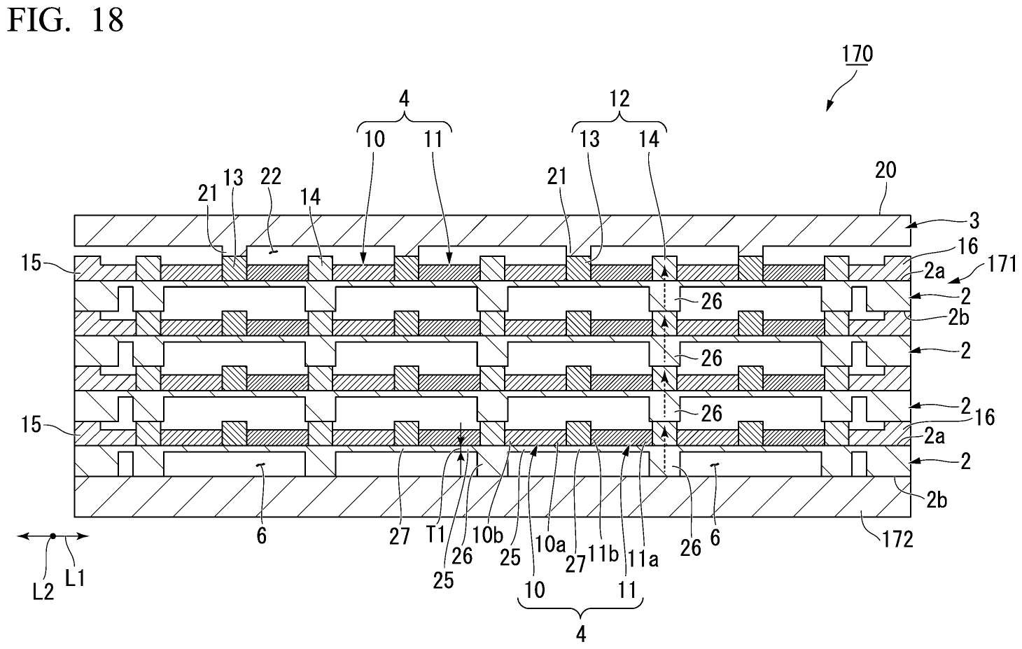

However, in a case in which heat is transferred from a side of the substrate 2 to the a side of thermoelectric conversion film 4, for example, as illustrated in FIG. 18, a thermoelectric conversion device 170 in which substrates 2 according to the first embodiment are piled up in multiple layers in the thickness direction may be used.

In addition, in the form illustrated in FIG. 18, the same reference signs will be assigned to the same parts as the constituent elements of the first embodiment, and description thereof will be omitted.

The thermoelectric conversion device 170 illustrated in FIG. 18 includes a thermoelectric conversion module 171 in which substrates 2, in which first thermoelectric conversion films 10, second thermoelectric conversion films 11, first electrodes 13, second electrodes 14, a first terminal 15, and a second terminal 16 are disposed on a first principal surface 2a, are piled up in the thickness direction in multiple layers.

In the example illustrated in FIG. 18, the thermoelectric conversion module 171 in which substrates 2 are piled up in four layers 4 is formed. However, the structure of the thermoelectric conversion module 171 is not limited to four layers and may be a multi-layer structure in which two or more layers are piled up.

In addition, the thermoelectric conversion device 170 includes a second heat transfer plate (a second heat transfer member according to the present disclosure) 172 that is disposed on a side of the second principal surface 2b of the substrate 2 positioned in the lowermost layer (the first layer) and transfers heat to/from this substrate 2. The second heat transfer plate 172 is a member having a flat plate shape functioning as a heat-receiving member in the thermoelectric conversion device 170, and a lower end face thereof is thermally bonded to a heat source not illustrated in the drawing. Accordingly, heat from a heat source that has been received from the second heat transfer plate 172 can be transferred to the substrate 2 positioned in the lowermost layer.

The second heat transfer plate 172 is formed using a material having higher thermal conductivity than the thermal conductivity of the air, is thermally bonded to first parts 26 of the substrate 2 positioned in the lowermost layer from the lower side, and transfers heat to/from the first parts 26 of the substrate 2 positioned in the lowermost layer rather than the facing portions 25 and second parts 27 of the substrate 2 positioned in the lowermost layer. Accordingly, heat received by the second heat transfer plate 172 can be transferred to the first parts 26 of the substrate 2 positioned in the lowermost layer rather than to the facing portions 25 and the second parts 27 of the substrate 2 positioned in the lowermost layer.

In other words, in the example illustrated in FIG. 18, the second heat transfer plate 172 transfers heat to/from the first parts 26 of the substrate 2 positioned in the lowermost layer than parts interposed between the first parts 26, which are adjacent to each other in the first direction L1, of the substrate 2 positioned in the lowermost layer (in other words, facing portions 25, second parts 27, and concave parts 6).

A first heat transfer plate 3 is disposed on a side of the first principal surface 2a of the substrate 2 positioned on an uppermost layer (the fourth layer) in the thermoelectric conversion module 171 and is bonded to first electrodes 13 disposed on the first principal surface 2a of this substrate 2, similar to the first embodiment, through convex parts 21 and insulating members not illustrated in the drawing.

In the thermoelectric conversion module 171, the substrate 2 positioned in any one of layers (the first to third layers) other than the uppermost layer is disposed such that a first principal surface 2a and a second principal surface 2b face each other with respect to the substrate 2 positioned in the layer above thereof.

Accordingly, second electrodes 14 positioned in any one of states (the first layer to third layer) other than the uppermost layer in the thermoelectric conversion module 171 are bonded to first parts 26 of the substrate 2 positioned on the layer above thereof. In this case, the second electrodes 14 may be bonded to the first parts 26 through other members such as paste materials not illustrated in the drawing.

Accordingly, in the thermoelectric conversion module 171, thermoelectric conversion films 4 positioned in any one of layers (the first to third layers) other than the uppermost layer are thermally bonded to first parts 26 of the substrate 2 positioned on the layer above thereof through the second electrodes 14 and transfer heat to/from the first parts 26 of the substrate 2 positioned in the layer above thereof rather than the facing portions 25 of the substrate 2 positioned on the layer above thereof. In this way, heat is transferred to the thermoelectric conversion film 4 of each layer through the first parts 26 of the substrate 2 of each layer rather than through the facing portions 25 of the substrate 2 of each layer.

In the example illustrated in FIG. 18, the thermoelectric conversion films 4 positioned in any one of layers other than the uppermost layer (the first to third layers) transfer heat to/from the first parts 26 of the substrate 2 positioned on the layer above thereof rather than through portions interposed between the first parts 26, which are adjacent to each other in the first direction L1, (in other words, the facing portions 25, the second part 27, and the concave parts 6) of the substrate 2 positioned in the layer above thereof.

In addition, in the thermoelectric conversion device 170 of this case, since heat received by the second heat transfer plate 172 is transferred to the substrate 2 positioned in the lowermost layer, the second electrodes 14 of each layer function as hot junctions, and the first electrodes 13 function as cold junctions. For this reason, the rear end portion 10a of the first thermoelectric conversion film 10 and the front end portion 11b of the second thermoelectric conversion film 11 in each layer function as end portions of the cold junction side, and the front end portion 10b of the first thermoelectric conversion film 10 and the rear end portion 11a of the second thermoelectric conversion film 11 function as end portions of the hot junction side.

### (Operation of Thermoelectric Conversion Device)

According to the thermoelectric conversion device 170 configured as described above, operations and effects similar to those of a case in which heat is transferred from a side of the first heat transfer plate 3 can be successfully achieved. In addition thereto, according to this thermoelectric conversion device 170, the thermoelectric conversion module 171 is included, and accordingly, dissipated heat can be effectively used, and power generation in the thermoelectric conversion film 4 of each layer can be achieved. Therefore, a large amount of generated power can be achieved with high efficiency.

In other words, according to this thermoelectric conversion device 170, as illustrated using a dotted-line arrow illustrated in FIG. 17, heat received by the second heat transfer plate 172 can be transferred to the second electrodes 14 positioned in the lowermost layer through the first parts 26 of the substrate 2 positioned in the lowermost layer with priority and can be transferred to the hot junction side of the first thermoelectric conversion film 10 and the second thermoelectric conversion film 11 positioned in the lowermost layer through this second electrode 14.

In addition, heat transferred from the first parts 26 of the substrate 2 positioned in the lowermost layer to the second electrodes 14 of the lowermost layer can be transferred to the second electrodes 14 positioned in the second layer through the first parts 26 of the substrate 2 positioned in the second layer and can be transferred to the hot junction sides of the first thermoelectric conversion film 10 and the second thermoelectric conversion film 11 positioned in the second layer through these second electrodes 14.

In this way, heat dissipated from a thermoelectric conversion film 4 through the second electrodes 14 can be transferred to the hot junction side of the thermoelectric conversion film 4 positioned in the layer above thereof through the first parts 26 of the substrate 2 positioned in the layer above of the thermoelectric conversion film 4, and accordingly, dissipated heat can be effectively used. Accordingly, power generation in the thermoelectric conversion film 4 of each layer can be achieved, and a large amount of generated power can be achieved with high efficiency.

In other words, according to this thermoelectric conversion device 170, the second heat transfer plate 172 performs a role similar to that of the first heat transfer plate 3 of the thermoelectric conversion device 90 according to the fifth embodiment illustrated in FIG. 10, and, when the flow of dissipated heat is focused on, operations and effects similar to those of the thermoelectric conversion device 90 illustrated in FIG. 10 can be achieved.

In addition, according to this thermoelectric conversion device 170, for example, the first heat transfer plate 3 can be used as a heat dissipation or cooling member. Accordingly, by using a heat dissipation or cooling effect using the first heat transfer plate 3, the cold junction sides of the first thermoelectric conversion film 10 and the second thermoelectric conversion film 11 positioned in the uppermost layer can be effectively cooled through the convex parts 21 and the first electrodes 13 positioned in the uppermost layer.

In addition, in a case in which heat is transferred from a side of the substrate 2 to the a side of thermoelectric conversion film 4, this can be applied not only to the first embodiment but also to each of all the embodiments and the modified examples thereof, and similar operations and effects can be successfully achieved in any of the cases.

For example, in the thermoelectric conversion device 40 according to the second embodiment illustrated in FIG. 5, in a case in which heat is transferred from a side of the substrate 2 to a side of the thermoelectric conversion film 4, the heat transferred to the substrate 2 can be effectively dissipated or cooled through the second parts 27 and the convex parts 21 of the substrate 2 and the first heat transfer plate 3 rather than being moved in the in-plane direction of the substrate 2. Accordingly, a temperature difference between the hot junction side and the cold junction side in the thermoelectric conversion elements 4 can be increased more effectively, and a large amount of generated power is easily achieved.

In addition, in the case of the thermoelectric conversion device 80 according to the fourth embodiment illustrated in FIG. 9, for example, the second heat transfer plate 81 can be caused to function as a heat-receiving member, and the first heat transfer plate 3 can be caused to function as a heat dissipation or cooling member. Accordingly, heat can be efficiently transferred to a side of the thermoelectric conversion film 4 through the substrate 2 through the second heat transfer plate 81, and a large amount of generated power can be achieved.

In addition, in the case of this thermoelectric conversion device 80, heat from the second heat transfer plate 81 can be easily transferred to the second electrodes 14 through the first parts 26 of the substrate 2, and accordingly, the second electrodes 14 function as hot junctions, and the first electrodes 13 function as cold junctions. For this reason, the rear end portion 10a of the first thermoelectric conversion film 10 and the front end portion 11b of the second thermoelectric conversion film 11 function as end portions of the cold junction side, and the front end portion 10b of the first thermoelectric conversion film 10 and the rear end portion 11a of the second thermoelectric conversion film 11 functions as end portions of the hot junction side.

However, also in this case, since the thickness T1 of at least the part of the facing portions 25 of the substrate 2 is formed thinner than at least another part of the substrate 2 other than the facing portions 25, heat transferred from the second heat transfer plate 81 to the substrate 2 can be inhibited from moving from the hot junction side to the cold junction side inside the substrate 2. Accordingly, a temperature difference between the hot junction side and the cold junction side in the thermoelectric conversion elements 4 can be increased, and a large amount of generated power can be achieved.

In addition, also in the case of the thermoelectric conversion device 90 according to the fifth embodiment illustrated in FIG. 10, heat may be transferred from a side of the substrate 2 positioned in the lowermost layer.

In such a case, heat received by the substrate 2 positioned in the lowermost layer can be transferred to the first electrodes 13 positioned in the lowermost layer through the second parts 27 of the substrate 2 positioned in the lowermost layer and can be transferred to the hot junction sides of the first thermoelectric conversion film 10 and the second thermoelectric conversion film 11 (in other words, a side of the rear end portion 10a of the first thermoelectric conversion film 10 and a side of the front end portion 11b of the second thermoelectric conversion film 11) positioned in the lowermost layer through these first electrodes 13.

At this time, since the thickness T1 of at least the part of the facing portions 25 of the substrate 2 positioned in the lowermost layer is formed thinner than at least another part of the substrate 2 other than the facing portions 25, movement of heat, which has been received from the substrate 2 positioned in the lowermost layer, from the hot junction side to the cold junction side inside the substrate 2 can be inhibited. Accordingly, by using a change in the thickness of the substrate 2, a decrease in the temperature difference occurring between the hot junction side and the cold junction side in the thermoelectric conversion elements 4 positioned in the lowermost layer due to the influence of conduction of heat through the substrate 2 positioned in the lowermost layer can be inhibited, and a large amount of generated power can be achieved.

In addition, heat transferred from the second parts 27 of the substrate 2 positioned in the lowermost layer to the first electrodes 13 of the lowermost layer can be transferred to the first electrodes 13 positioned in the second layer through the second parts 27 of the substrate 2 positioned in the second layer and can be transferred to the hot junction sides of the first thermoelectric conversion film 10 and the second thermoelectric conversion film 11 positioned in the second layer through these first electrodes 13.

In this way, heat dissipated through the second parts 27 of the substrate 2 can be transferred to the hot junction sides of the first thermoelectric conversion film 10 and the second thermoelectric conversion film 11 through the second parts 27 of the substrate 2 positioned in the layer above of the substrate 2, and accordingly, the dissipated heat can be effectively used. Accordingly, power generation in the thermoelectric conversion film 4 of each layer can be achieved, and a large amount of generated power can be achieved with high efficiency.

As described above, in the thermoelectric conversion device 90 according to the fifth embodiment illustrated in FIG. 10, also in a case in which heat is transferred from a side of the substrate 2 positioned on the lowermost layer, operations and effects similar to those of the case in which heat is transferred from a side of the first heat transfer plate 3 can be successfully achieved.

In addition thereto, in a case in which heat is transferred from a side of the substrate 2 positioned in the lowermost layer, for example, since the first heat transfer plate 3 can be caused to function as a heat dissipation or cooling member or the like, by using a heat dissipation or cooling effect using the first heat transfer plate 3, heat transferred to the substrate 2 positioned in the uppermost layer can be dissipated or cooled through the convex parts 21 and the first heat transfer plate 3 rather than being moved in the in-plane direction of the substrate 2 positioned in the uppermost layer. Accordingly, as a result, a temperature difference between the hot junction side and the cold junction side of the thermoelectric conversion elements 4 of each layer can be effectively increased, and a large amount of generated power is easily achieved.

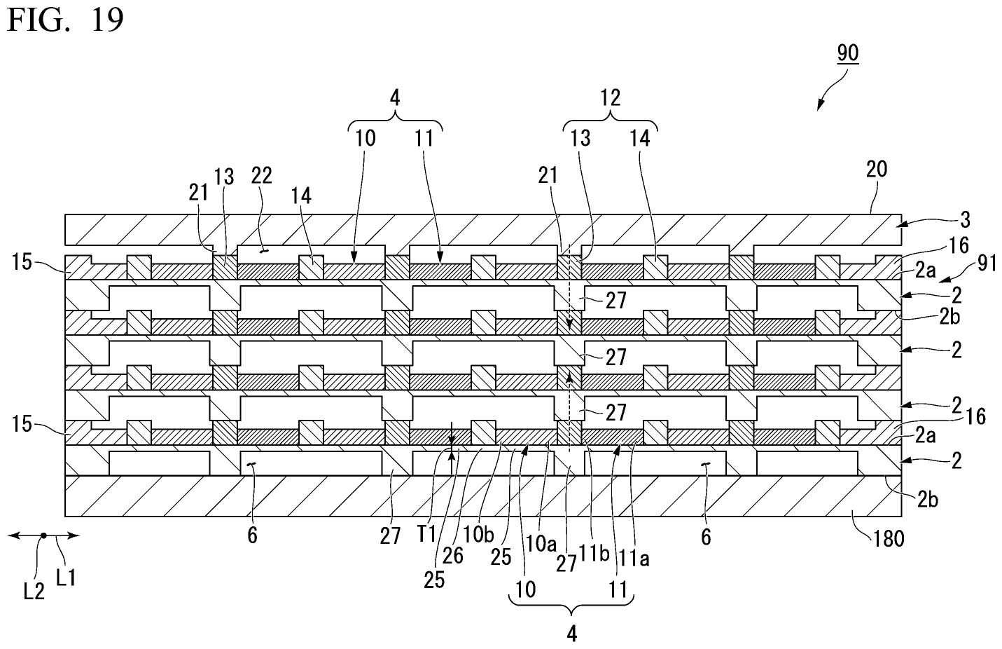

Meanwhile, in the thermoelectric conversion device 90 according to the fifth embodiment illustrated in FIG. 10, in a case in which heat is transferred from a side of the substrate 2 positioned in the lowermost layer, for example, as illustrated in FIG. 19, a second heat transfer plate (a second heat transfer member according to the present disclosure) 180 that transfers heat to/from the substrate 2 positioned in the lowermost layer may be disposed on a side of the second principal surface 2b of the substrate 2 positioned in the lowermost layer (the first layer).

The second heat transfer plate 180 is a flat plate-shaped member functioning as a heat-receiving member in the thermoelectric conversion device 90, and a lower end face thereof is thermally bonded to a heat source not illustrated in the drawing. Accordingly, heat from the heat source that has been received by the second heat transfer plate 180 can be transferred to the first electrodes 13 positioned in the lowermost layer through the second parts 27 of the substrate 2 positioned in the lowermost layer and can be transferred to the hot junction sides of the first thermoelectric conversion film 10 and the second thermoelectric conversion film 11 positioned in the lowermost layer through these first electrodes 13.

In this way, by including the second heat transfer plate 180, it becomes easy to transfer heat to the substrate 2 positioned in the lowermost layer with high efficiency. Accordingly, a temperature difference between the hot junction side and the cold junction side in the thermoelectric conversion elements 4 of each layer can be increased effectively, and a large amount of generated power can be easily achieved.

In addition, in a case in which the second heat transfer plate 180 is included, heat may be received using both the second heat transfer plate 180 and the first heat transfer plate 3 by causing both the second heat transfer plate 180 and the first heat transfer plate 3 to function as heat-receiving members.

In such a case, as denoted using a dotted-line arrow illustrated in FIG. 19, heat received by the first heat transfer plate 3 can be transferred to the first electrodes 13 positioned in the uppermost layer (the fourth layer) with priority through the convex parts 21 and can be transferred to the hot junction sides of the first thermoelectric conversion film 10 and the second thermoelectric conversion film 11 positioned on the uppermost layer through these first electrodes 13.

In addition, heat transferred to the first electrodes 13 positioned in the uppermost layer can be transferred to the first electrodes 13 positioned in the third layer through the second parts 27 of the substrate 2 positioned in the uppermost layer and can be transferred to the hot junction sides of the first thermoelectric conversion film 10 and the second thermoelectric conversion film 11 positioned in the third layer through these first electrodes 13.

Simultaneously with this, as denoted using a dotted-line arrow illustrated in FIG. 18, heat received by the second heat transfer plate 180 can be transferred to the first electrodes 13 positioned in the lowermost layer through the second parts 27 of the substrate 2 positioned in the lowermost layer and can be transferred to the hot junction sides of the first thermoelectric conversion film 10 and the second thermoelectric conversion film 11 positioned in the lowermost layer through these first electrodes 13.

In addition, heat transferred to the first electrodes 13 of the lowermost layer can be transferred to the first electrodes 13 positioned in the second layer through the second parts 27 of the substrate 2 positioned in the second layer and can be transferred to the hot junction sides of the first thermoelectric conversion film 10 and the second thermoelectric conversion film 11 positioned in the second layer through these first electrodes 13.

Accordingly, also in a case in which heat is received by both the second heat transfer plate 180 and the first heat transfer plate 3, dissipated heat can be effectively used. Accordingly, power generation can be achieved in the thermoelectric conversion film 4 of each layer, and a large amount of generated power can be achieved with high efficiency.

In addition, in a case in which heat is received by both the second heat transfer plate 180 and the first heat transfer plate 3, for example, by supplying an air flow such as a cooling wind or the like to the thermoelectric conversion device 90 in the second direction L2, heat dissipation can be appropriately performed from the inside to the outside of the thermoelectric conversion device 90.

Furthermore, also in the case of the thermoelectric conversion device 100 according to the sixth embodiment illustrated in FIG. 11, heat may be transferred from a side of the second heat transfer plate 101.

In such a case, the second heat transfer plate 101 may be used as a heat-receiving member. In addition, since heat received by the second heat transfer plate 101 is transferred to the substrate 2 positioned in the lowermost layer, the second electrodes 14 of each layer function as hot junctions, and the first electrodes 13 function as cold junctions. For this reason, the rear end portion 10a of the first thermoelectric conversion film 10 and the front end portion 11b of the second thermoelectric conversion film 11 in each layer function as end portions of the cold junction side, and the front end portion 10b of the first thermoelectric conversion film 10 and the rear end portion 11a of the second thermoelectric conversion film 11 function as end portions of the hot junction side.

According to the thermoelectric conversion device 100 of this case, heat received by the second heat transfer plate 101 can be transferred to the second electrodes 14 positioned in the lowermost layer through the convex parts 102 and the first parts 26 of the substrate 2 positioned in the lowermost layer and can be transferred to the hot junction sides of the first thermoelectric conversion film 10 and the second thermoelectric conversion film 11 positioned in the lowermost layer through these second electrodes 14.

At this time, since the thickness T1 of at least the part of the facing portions 25 of the substrate 2 positioned in the lowermost layer is formed thinner than at least another part of the substrate 2 other than the facing portions 25, movement of heat, which has been transferred to the substrate 2 positioned in the lowermost layer, from the hot junction side to the cold junction side inside the substrate 2 can be inhibited. Accordingly, by using a change in the thickness of the substrate 2, a decrease in the temperature difference occurring between the hot junction side and the cold junction side in the thermoelectric conversion elements 4 positioned in the lowermost layer due to the influence of conduction of heat through the substrate 2 positioned in the lowermost layer can be inhibited, and a large amount of generated power can be achieved.

In addition, heat transferred from the first parts 26 of the substrate 2 positioned in the lowermost layer to the second electrodes 14 of the lowermost layer can be transferred to the second electrodes 14 positioned in the second layer through the first parts 26 of the substrate 2 positioned in the second layer and can be transferred to the hot junction sides of the first thermoelectric conversion film 10 and the second thermoelectric conversion film 11 positioned in the second layer through these second electrodes 14.

In this way, heat dissipated through the first parts 26 of the substrate 2 can be transferred to the hot junction sides of the first thermoelectric conversion film 10 and the second thermoelectric conversion film 11 through the first parts 26 of the substrate 2 positioned in the layer above of the substrate 2, and accordingly, the dissipated heat can be effectively used. Accordingly, power generation in the thermoelectric conversion film 4 of each layer can be achieved, and a large amount of generated power can be achieved with high efficiency.

As described above, in the thermoelectric conversion device 100 according to the sixth embodiment illustrated in FIG. 11, also in a case in which heat is transferred from a side of the second heat transfer plate 101, operations and effects similar to those of a case in which heat is transferred from a side of the first heat transfer plate 3 can be successfully achieved.

In addition, in a case in which heat is transferred from a side of the second heat transfer plate 101, for example, since the first heat transfer plate 3 can be caused to function as a heat dissipation or cooling member or the like, by using a heat dissipation or cooling effect using the first heat transfer plate 3, the cold junction sides of the first thermoelectric conversion film 10 and the second thermoelectric conversion film 11 of each layer can be effectively cooled. Accordingly, as a result, a temperature difference between the hot junction side and the cold junction side of the thermoelectric conversion elements 4 of each layer can be effectively increased, and a large amount of generated power is easily achieved.

### INDUSTRIAL APPLICABILITY

According to the present disclosure, a large amount of generated power can be achieved using a change in the thickness of a substrate, and a high-quality and high-performance thermoelectric conversion device having superior thermoelectric conversion efficiency can be achieved. Therefore, there is industrial applicability.

### REFERENCE SIGNS LIST

1, 30, 40, 50, 60, 70, 80, 90, 100, 110, 120, 140, 150, 160, 170 Thermoelectric conversion device
2 Substrate
2a First principal surface (first surface)
2b Second principal surface (second surface)
3 First heat transfer plate (first heat transfer member)
4, 151 Thermoelectric conversion film (thermoelectric conversion element)
13 First electrode (heat transfer part)
21 Convex part (heat transfer part)
22 Air gap portion (low heat conduction part)
25 Facing portion of substrate
26 First part of substrate
27 Second part of substrate
81, 101, 172, 180 Second heat transfer plate (second heat transfer member)
91, 105, 171 Thermoelectric conversion module
121 Low heat conduction member (low heat conduction part)

1. A thermoelectric conversion device, comprising:
a substrate that includes a first surface and a second surface facing each other in a thickness direction;
thermoelectric conversion elements that are disposed on a side of the first surface of the substrate; and
a plurality of heat transfer parts that are formed with spaces interposed therebetween in a first direction along an in-plane direction of the substrate, and that are configured to transfer heat from/to the thermoelectric conversion elements,
wherein a low heat conduction part having a lower thermal conductivity than a thermal conductivity of the heat transfer parts is disposed between heat transfer parts adjacent to each other in the first direction, and
wherein a thickness of at least a part of facing portions of the substrate that face the thermoelectric conversion elements in the thickness direction is smaller than a thickness of at least a part of other part of the substrate.

2. The thermoelectric conversion device according to claim 1, further comprising:
a first heat transfer member disposed on the side of the first surface of the substrate,
wherein the thermoelectric conversion elements and the heat transfer parts are disposed on a further substrate side than the first heat transfer member.

3. The thermoelectric conversion device according to claim 1, wherein the low heat conduction part is an air gap portion.

4. The thermoelectric conversion device according to claim 1,
wherein a thickness of first parts of the substrate is larger than the thickness of at least the part of the facing portions, and
wherein each of the first parts of the substrate is positioned in a middle of the heat transfer parts, which are adjacent to each other in the first direction, in the first direction.

5. The thermoelectric conversion device according to claim 1,
wherein a thickness of at least a part of second parts of the substrate that face the heat transfer parts in the thickness direction is larger than the thickness of at least the part of the facing portions.

6. The thermoelectric conversion device according to claim 1,
wherein a thickness of first parts of the substrate is larger than the thickness of at least the part of the facing portions,
wherein each of the first parts of the substrate is positioned in a middle of the heat transfer parts, which are adjacent to each other in the first direction, in the first direction, and
wherein a thickness of at least a part of second parts of the substrate that faces the heat transfer parts in the thickness direction is larger than the thickness of at least the part of the facing portions.

7. The thermoelectric conversion device according to claim 6,
wherein a width of the part of the second parts, which have a larger thickness than the thickness of at least the part of the facing portions, in the first direction is larger than a width of a part of the first parts, which is larger than the thickness of at least the part of the facing portions, in the first direction.

8. The thermoelectric conversion device according to claim 6,
wherein a width of a part of the first parts, which have a larger thickness than the thickness of at least the part of the facing portions, in the first direction is larger than a width of the part of the second parts, which is larger than the thickness of at least the part of the facing portions, in the first direction.

9. The thermoelectric conversion device according to claim 4, further comprising:
a second heat transfer member disposed on a side of the second surface of the substrate,
wherein the second heat transfer member is thermally bonded to the first parts of the substrate and is configured to transfer heat from/to the first parts rather than the facing portions.

10. The thermoelectric conversion device according to claim 5, further comprising:
a thermoelectric conversion module in which substrates with the thermoelectric conversion elements are piled up in the thickness direction in multiple layers,
wherein, as a direction from the second surface to the first surface is defined as an upward direction, the heat transfer parts are configured to transfer heat from/to the thermoelectric conversion element positioned in an uppermost layer in the thickness direction among the thermoelectric conversion elements piled up in multiple layers,
wherein the thermoelectric conversion elements positioned in a layer other than the uppermost layer in the thickness direction among the thermoelectric conversion elements piled up in multiple layers are thermally bonded to the second parts of each of the substrates positioned in a layer above thereof, and are configured to transfer heat from/to the second parts of each of the substrates positioned in the layer above thereof rather than the facing portions of each of the substrates positioned in the layer above thereof.

11. The thermoelectric conversion device according to claim 10, further comprising:
a second heat transfer member disposed on a side of the second surface of the substrate positioned in a lowermost layer in the thickness direction among the substrates piled up in multiple layers,
wherein the second heat transfer member is thermally bonded to the second parts of the substrate positioned in the lowermost layer among the substrates piled up in multiple layers, and
wherein the second heat transfer member is configured to transfer heat from/to the second parts of the substrate positioned in the lowermost layer rather than the facing portions of the substrate positioned in the lowermost layer.

12. The thermoelectric conversion device according to claim 4, further comprising:
a thermoelectric conversion module in which substrates with the thermoelectric conversion elements are piled up in the thickness direction in multiple layers,
wherein, as a direction from the second surface to the first surface is defined as an upward direction, the heat transfer parts are configured to transfer heat from/to the thermoelectric conversion element positioned in an uppermost layer in the thickness direction among the thermoelectric conversion elements piled up in multiple layers, and
wherein the thermoelectric conversion elements positioned in a layer other than the uppermost layer in the thickness direction among the thermoelectric conversion elements piled up in multiple layers are thermally bonded to the first parts of each of the substrates positioned in a layer above thereof, and are configured to transfer heat from/to the first parts of each of the substrates positioned in the layer above thereof rather than the facing portions of each of the substrates positioned in the layer above thereof.

13. The thermoelectric conversion device according to claim 6, further comprising:
a thermoelectric conversion module in which substrates with the thermoelectric conversion elements are piled up in the thickness direction in multiple layers,
wherein, as a direction from the second surface to the first surface is defined as an upward direction, the heat transfer parts are configured to transfer heat from/to the thermoelectric conversion element positioned in an uppermost layer in the thickness direction among the thermoelectric conversion elements piled up in multiple layers, and
wherein the thermoelectric conversion elements positioned in a layer other than the uppermost layer in the thickness direction among the thermoelectric conversion elements piled up in multiple layers are thermally bonded to the first parts and the second parts of each of the substrates positioned in a layer above thereof, and are configured to transfer heat from/to the first parts and the second parts of each of the substrates positioned in the layer above thereof rather than the facing portions of each of the substrates positioned in the layer above thereof.

14. The thermoelectric conversion device according to claim 12, further comprising:
a second heat transfer member disposed on a side of the second surface of the substrate positioned in a lowermost layer in the thickness direction among the substrates piled up in multiple layers,
wherein the second heat transfer member is thermally bonded to the first parts of the substrate positioned in the lowermost layer among the substrates piled up in multiple layers, and the second heat transfer member is configured to transfer heat from/to the first parts of the substrate positioned in the lowermost layer rather than the facing portions of the substrate positioned in the lowermost layer.

15. The thermoelectric conversion device according to claim 7, further comprising:
a thermoelectric conversion module in which substrates with the thermoelectric conversion elements are piled up in the thickness direction in multiple layers,
wherein, as a direction from the second surface to the first surface is defined as an upward direction, the heat transfer parts are configured to transfer heat from/to the thermoelectric conversion element positioned in an uppermost layer in the thickness direction among the thermoelectric conversion elements piled up in multiple layers, and
wherein the thermoelectric conversion elements positioned in a layer other than the uppermost layer in the thickness direction among the thermoelectric conversion elements piled up in multiple layers are thermally bonded to the first parts and the second parts of each of the substrates positioned in a layer above thereof, and are configured to transfer heat from/to the first parts and the second parts of each of the substrates positioned in the layer above thereof rather than the facing portions of each of the substrates positioned in the layer above thereof.

16. The thermoelectric conversion device according to claim 8, further comprising:
a thermoelectric conversion module in which substrates with the thermoelectric conversion elements are piled up in the thickness direction in multiple layers,
wherein, as a direction from the second surface to the first surface is defined as an upward direction, the heat transfer parts are configured to transfer heat from/to the thermoelectric conversion element positioned in an uppermost layer in the thickness direction among the thermoelectric conversion elements piled up in multiple layers, and
wherein the thermoelectric conversion elements positioned in a layer other than the uppermost layer in the thickness direction among the thermoelectric conversion elements piled up in multiple layers are thermally bonded to the first parts and the second parts of each of the substrates positioned in a layer above thereof, and are configured to transfer heat from/to the first parts and the second parts of each of the substrates positioned in the layer above thereof rather than the facing portions of each of the substrates positioned in the layer above thereof.

17. The thermoelectric conversion device according to claim 13, further comprising:
a second heat transfer member disposed on a side of the second surface of the substrate positioned in a lowermost layer in the thickness direction among the substrates piled up in multiple layers,
wherein the second heat transfer member is thermally bonded to the first parts of the substrate positioned in the lowermost layer among the substrates piled up in multiple layers, and the second heat transfer member is configured to transfer heat from/to the first parts of the substrate positioned in the lowermost layer rather than the facing portions of the substrate positioned in the lowermost layer.

18. The thermoelectric conversion device according to claim 15, further comprising:
a second heat transfer member disposed on a side of the second surface of the substrate positioned in a lowermost layer in the thickness direction among the substrates piled up in multiple layers,
wherein the second heat transfer member is thermally bonded to the first parts of the substrate positioned in the lowermost layer among the substrates piled up in multiple layers, and the second heat transfer member is configured to transfer heat from/to the first parts of the substrate positioned in the lowermost layer rather than the facing portions of the substrate positioned in the lowermost layer.

19. The thermoelectric conversion device according to claim 16, further comprising:
a second heat transfer member disposed on a side of the second surface of the substrate positioned in a lowermost layer in the thickness direction among the substrates piled up in multiple layers,
wherein the second heat transfer member is thermally bonded to the first parts of the substrate positioned in the lowermost layer among the substrates piled up in multiple layers, and the second heat transfer member is configured to transfer heat from/to the first parts of the substrate positioned in the lowermost layer rather than the facing portions of the substrate positioned in the lowermost layer.
